(19) United States
(12) Patent Application Publication
(10) Pub. No.: US 2025/0232097 A1
(43) Pub. Date: Jul. 17, 2025

(54) Finite Element Analysis Generative Artificial Intelligence

(71) Applicant: Intergraph Corporation, Madison, AL (US)

(72) Inventor: Ravindra Ozarker, San Jose, CA (US)

(21) Appl. No.: 19/022,399

(22) Filed: Jan. 15, 2025

Related U.S. Application Data
(63) Continuation-in-part of application No. 18/414,274, filed on Jan. 16, 2024.

(51) Int. Cl. G06F 30/27; G06F 30/12

(52) U.S. Cl. CPC G06F 30/27; G06F 30/12

(57) ABSTRACT

Illustrative embodiments operate in a computer-aided design environment to facilitate finite element analysis of a previously-constructed multi-component structure. Some illustrative embodiments employ artificial intelligence to assess images of the previously-constructed multi-component structure to produce a mesh suitable for finite element analysis of the previously-constructed multi-component structure. Some illustrative embodiments employ artificial intelligence to assess images of a previously-constructed multi-component structure to produce a CAD drawing of the previously-constructed structure.

### RELATED APPLICATIONS

This application is a Continuation-In-Part of U.S. patent application Ser. No. 18/414,274, filed Jan. 16, 2024 and titled “Shadow-Based Component Finite Element Analysis” and naming Ravindra Ozarker as inventor [Attorney Docket No. 37402-20801].

The disclosure of each of the foregoing is incorporated herein by reference, in its entirety.

### FIELD

Illustrative embodiments of the invention generally relate to computer-aided design of physical systems and, more particularly, various embodiments relate to finite element analysis of physical systems.

### BACKGROUND

Finite element analysis (“FEA”) is a computer-implemented process of analyzing a physical object using models and simulations to assess how the object will behave under various physical conditions.

For example, an engineer designing a new (i.e., as-yet unbuilt) structure typically performs finite element analysis on a model of the structure prior to finalizing the design, to determine whether the design is structurally sound.

For a pre-existing structure, engineers may want to perform finite element analysis and quickly perform a rough qualification. Performing finite element analysis on a pre-existing structure is more difficult than on an un-built structure being designed, in that the pre-existing structure may have been designed by an older generation of engineers using older design codes and philosophies, and may be made more difficult if accurate and up-to-date models of the pre-existing structure are not available. Typically, the engineer must first create one or more models of the existing structure, or at least a subset of components of the existing structure, prior to performing finite element analysis.

Many design engineers use computer-aided design systems to design new structures. Some computer-aided design systems have some finite element analysis capabilities. In the past, engineers would use complicated hard-to-use software separate from the CAD system to perform finite element analysis. These products would use three noded plate elements or six-noded wedge elements with different local axis. It would be very difficult for a normal practicing engineer to understand the stress directions and results to qualify their designs.

One challenge with these FEA-based procedures is the complexity which requires proper connectivity between the elements. This task requires engineers to look at the boundary of the components and provide common points, which could be extremely difficult even with a simple problem of a pipe connecting to a vessel.

### SUMMARY OF VARIOUS EMBODIMENTS

Illustrative embodiments operate in a computer-aided design environment to facilitate finite element analysis of a multi-component system, which system includes a master component coupled to a dependent component.

Performing Finite Element Analysis on an object or system conventionally requires a user to have considerable experience in preparing a model of the object or system prior to performing Finite Element Analysis on the model. Such a user must be experienced in preparing models and inputs for Finite Element Analysis.

In contrast, illustrative embodiments enable a CAD operator to perform Finite Element Analysis on a multi-component system, even when that CAD operator is not experienced in preparing models and inputs for Finite Element Analysis.

Also, performing Finite Element Analysis on existing structures is more difficult than performing Finite Element Analysis on a structure that has not yet been built, but which exists in a CAD model. This is because, at least in part, a model of the existing structure must be created for use as input to Finite Element Analysis. Illustrative embodiments enable a CAD operator to perform Finite Element Analysis on a pre-existing structure by making it easier to create a model of the pre-existing structure, even when a CAD model of the pre-existing structure is not available.

A first embodiment discloses a method, including providing an artificial intelligence image generator trained to generate a computer mesh file from a plurality of photographs of a system; obtaining a plurality of photographs of a previously-constructed system; and causing the artificial intelligence to generate a computer mesh file of the previously-constructed system, which computer mesh file is configured for finite element analysis by a finite element analysis system.

In some such embodiments, the plurality of photographs of the previously-constructed system includes a collage of the plurality of photographs, in which the plurality of photographs are arranged relative to one another according to a previously-defined fixed pattern.

In such embodiments, providing an artificial intelligence trained to generate a computer mesh file from a plurality of photographs of a system includes: training an artificial intelligence image-to-image generator using a generative artificial intelligence including a source of reference images of previously-constructed reference systems, each such image including a mesh suitable for finite element analysis, and a discriminator, the discriminator including a second artificial intelligence trained to discriminate between an image generated by the generator and one or more reference images.

In some embodiments, each reference image includes a collage of a plurality of images of a corresponding previously-constructed reference system, such plurality of images arranged in the collage relative to one another according to the previously-defined pattern.

In some embodiments, providing an artificial intelligence trained to generate a computer mesh file from a plurality of photographs of a system includes: training an artificial intelligence image-to-image generator by providing a plurality of images to a variational autoencoder, where each image of the plurality of images includes a previously-constructed system having a mesh suitable for finite element analysis.

In some embodiments, the computer mesh file includes a plurality of triangular mesh elements. In some embodiments, the computer mesh file includes a plurality of four-noded mesh elements. In some embodiments, the computer mesh file includes a plurality of nodes, each node is a member of at least two mesh elements.

In some embodiments, the plurality of photographs of the previously-constructed system includes photographs collectively showing a 360 degree view of the previously-constructed system.

Some embodiments further include performing finite element analysis on the computer mesh file.

In another embodiments, a computer-implemented system includes: an artificial intelligence image generator module trained to generate a computer mesh file from a plurality of photographs of a system; a source of photographs of a previously-constructed system, the source in data communication with the artificial intelligence image generator module; and a memory configured to store a corresponding computer mesh file generated from the photographs of the previously-constructed system by the artificial intelligence image generator.

Some such systems also include a finite element analysis module in data communication with the memory and configured to perform finite element analysis on the corresponding computer mesh file.

Some embodiments also include a drone having a camera, the drone craft configured to fly near the previously-constructed system and capture the photographs of a previously-constructed system.

In some embodiments, the artificial intelligence image generator module is trained by a generative artificial intelligence including a source of reference images of previously-constructed reference systems, each such image including a mesh suitable for finite element analysis, and a discriminator, the discriminator including a second artificial intelligence trained to discriminate between an image generated by the generator and one or more reference images.

In some embodiments, the artificial intelligence image generator module is trained by providing a large set of images to a variational autoencoder, where each image of the large set of images includes a previously-constructed system having a mesh suitable for finite element analysis.

Yet another embodiment includes a non-transitory computer-readable medium having computer executable code thereon, the computer executable code, when executed by a computer system, causing the computer system to perform a method, the code including: code for providing an artificial intelligence image generator trained to generate a computer mesh file from a plurality of photographs of a system; code for obtaining a plurality of photographs of a previously-constructed system, said plurality of photographs of the previously-constructed system including a collage of the plurality of photographs, in which the plurality of photographs are arranged relative to one another according to a previously-defined pattern; and code for causing the artificial intelligence to generate a computer mesh file of the previously-constructed system, which computer mesh file is configured for finite element analysis by a finite element analysis system.

In some embodiments, the artificial intelligence image generator was trained using a generative artificial intelligence including a source of reference images of previously-constructed reference systems, each such image including a mesh suitable for finite element analysis, and a discriminator, the discriminator including a second artificial intelligence trained to discriminate between an image generated by the generator and one or more reference images. In some embodiments, each reference image includes a collage of a plurality of images of a corresponding previously-constructed reference system, such plurality of images arranged in the collage relative to one another according to the previously-defined pattern.

In some embodiments, the artificial intelligence image generator was trained by providing a large set of images to a variational autoencoder, where each image of the large set of images includes a previously-constructed system having a mesh suitable for finite element analysis.

In some embodiments, the computer mesh file includes a plurality of nodes, each node is a member of at least two mesh elements.

Other embodiments are directed to creating a computer-aided design drawing of a previously-constructed system (e.g., a previously-constructed structure).

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1A schematically illustrates an embodiment of a system for finite element analysis of a digital model of an interface between a master component and a dependent component of a physical apparatus;

FIG. 1B schematically illustrates a block diagram of an embodiment of a system for finite element analysis of a digital model of an interface between a master component and a dependent component of a physical apparatus;

FIG. 2A is a flowchart of an embodiment of a method for performing a finite element analysis of a digital model of an interface between a master component and a dependent component of a physical apparatus;

FIG. 2B schematically illustrates a user interface configured to receive specification of a number of points;

FIG. 3 is a flowchart of an embodiment of a method for casting a simulated shadow in a computer system;

FIG. 4 is a flowchart of an embodiment of a method for modeling an existing structure;

FIG. 5A schematically illustrates an embodiment of a cylindrical multi-component system;

FIG. 5B schematically illustrates an embodiment of components of a cylindrical multi-component system;

FIG. 5C schematically illustrates an embodiment of a dependent component of a cylindrical multi-component system;

FIG. 5D schematically illustrates an embodiment of a rectangular multi-component system;

FIG. 5E schematically illustrates an embodiment of components of a rectangular multi-component system;

FIG. 6A schematically illustrates an embodiment of an embodiment of casting a direct shadow on a master component;

FIG. 6B: A schematically illustrates an embodiment a shadow as cast on a master component;

FIG. 7A schematically illustrates an embodiment of casting an intermediate shadow on a shadow plane;

FIG. 7B schematically illustrates an embodiment of casting an intermediate shadow on a shadow plane;

FIG. 7C schematically illustrates an embodiment of casting an intermediate shadow on a shadow plane;

FIG. 8A schematically illustrates an embodiment of points derived from a shadow;

FIG. 8B schematically illustrates an embodiment of points derived from a shadow;

FIG. 8C schematically illustrates an embodiment of concentric rings of points derived from a shadow;

FIG. 8D schematically illustrates an embodiment of a mesh defined from concentric rings of points derived from a shadow;

FIG. 8E schematically illustrates an embodiment of a mesh defined from a plurality of points;

FIG. 8F schematically illustrates an embodiment of a triangular mesh element;

FIG. 9A schematically illustrates an embodiment of a drone inspecting a multi-component system;

FIG. 9B schematically illustrates an embodiment of a compiled set of images of a multi-component system;

FIG. 9C schematically illustrates an embodiment of a drone circumnavigating a previously-constructed system;

FIG. 10A is a flowchart of an embodiment of a method for creating a model of a previously-constructed structure for finite element analysis;

FIG. 10B schematically illustrates a model of a previously-constructed system and an associated mesh;

FIG. 11A is a flowchart of an embodiment of a method for creating a CAD drawing of a previously-constructed structure for finite element analysis;

FIG. 11B schematically illustrates a CAD drawing created using the method of FIG. 11A;

FIG. 12A is a flowchart of an embodiment of a method for creating a model of a previously-constructed structure, for finite element analysis, from a CAD model;

FIG. 12B schematically illustrates an embodiment of a mesh file on a generated CAD model;

FIG. 13 schematically illustrates a Generative Adversarial Network

### DESCRIPTION OF ILLUSTRATIVE EMBODIMENTS

Illustrative embodiments present an improvement over methods and systems for performing finite element analysis of a multi-component (i.e., a system that includes a plurality of physically connected components), even if that engineer does not have the expertise typically held by an engineer of ordinary skill in the field of finite element analysis. A typical computer-aided design system operator does not have the skills or experience to perform finite element analysis on a finite element analysis system.

Some embodiments enable an engineer using a computer-aided design system to perform finite element analysis on a multi-component system being designed by the engineer.

Some embodiments enable an engineer using a computer-aided design system to perform finite element analysis on a pre-existing (i.e., already-built) multi-component system. For example, in some embodiments, measurements of a pre-existing multi-component system may be translated into models on the computer-aided design system, and finite element analysis performed on the models. Some embodiments may scan a pre-existing multi-component system using a scanning modality, such as a scanning apparatus that produces a point cloud of the system. For example, some embodiments scan the pre-existing multi-component system using a scanner mounted to a drone.

Some embodiments allow an engineer to connect two or more components easily without having to deal with complex functions to represent the intersection of the curve or making any assumptions. This feature can be implemented in a software easily to create four-noded meshes to simplify the interpretation of the results.

Some embodiments implemented as a computer program product having a computer usable medium with computer readable program code thereon. The computer readable code may be read and utilized by a computer system in accordance with conventional processes.

Illustrative embodiments operate in a computer-aided design environment to facilitate finite element analysis of a multi-component system, which system includes a master component coupled to a dependent component. Illustrative embodiments cast a shadow of an end of the dependent component, and derive mesh node points on the surface of the master component from the shadow. Illustrative embodiments then form a mesh from the mesh node points, which mesh is input to a finite element analysis engine.

Definitions: As used in this description and the accompanying claims, the following terms shall have the meanings indicated, unless the context otherwise requires.

A “set” includes at least one member. For example, a set of photographs may include as few as a single photograph, or may include a plurality of photographs.

The term “CAD” means “computer-aided design.”

The term “CAD model” means a computer-aided design model of a structure or apparatus expressed as computer data. A CAD model may be a three-dimensional (“3D”) model, although such a 3D model may be displayed as a two-dimensional model on a computer screen. Creation of a CAD model may include creating the CAD model via 3D modeling.

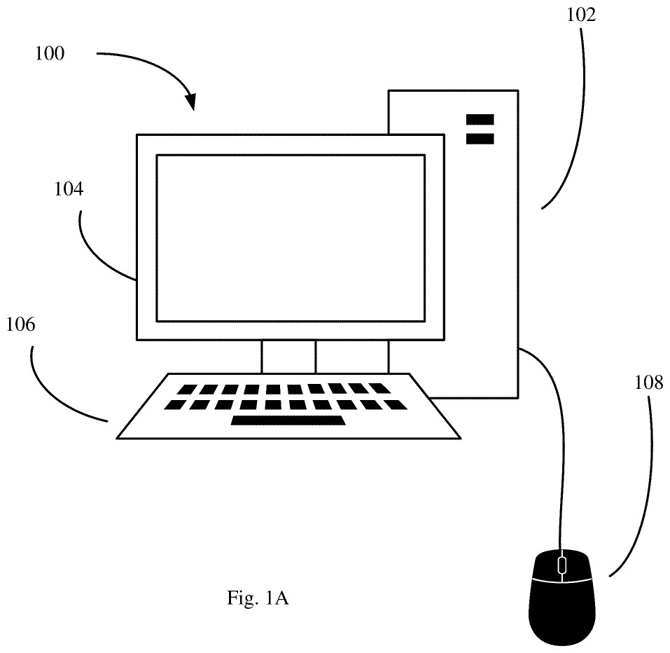

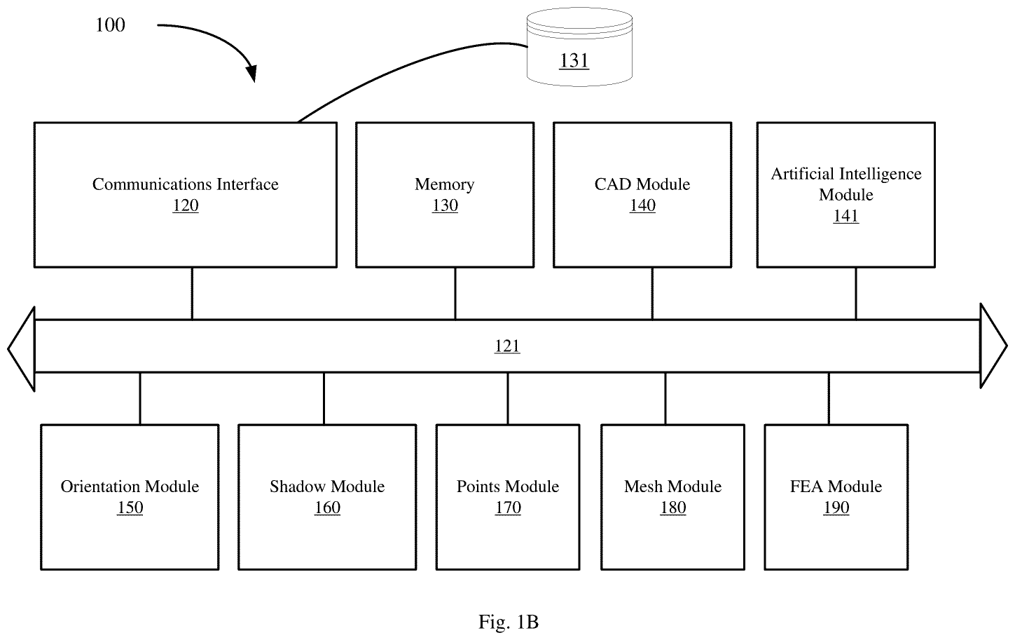

FIG. 1A schematically illustrates an embodiment of a CAD system 100 for finite element analysis of a digital model of an interface between a master component and a dependent component of a physical apparatus. The system includes a central processing unit 102 in data communication with a computer monitor having a display screen 104, a keyboard 106, and a computer mouse 108. A system operator may use the keyboard 106 and/or mouse 108 to provide use input to the system, and the central processing unit 103 may display images (e.g., CAD images and finite element analysis images) on the screen 104.

FIG. 1B schematically illustrates a block diagram of an embodiment of a system 100 for finite element analysis of a digital model of an interface between a master component and a dependent component of a physical apparatus. The system 100 includes a set of modules interconnected in data communication via a communications bus 121. The modules include a communications interface 120 configured to communicate with other computers or systems (e.g., a network; a cloud of components; a remote database 131). The system also includes a memory 130 which may store, among other things, CAD designs and executable software. The system also includes a CAD module 140 configured to render an image of the CAD drawing for display on a screen 104; an orientation module 150 configured to orient a dependent component relative to a master component as described herein, a shadow module 160 configured to display a CAD cast a shadow of a component in a CAD drawing; a points module 170 configured to select points from a shadow; a mesh module 180 configured to generate a finite element analysis mesh from selected points; and a finite element analysis module 190 configured to perform finite element analysis using the mesh.

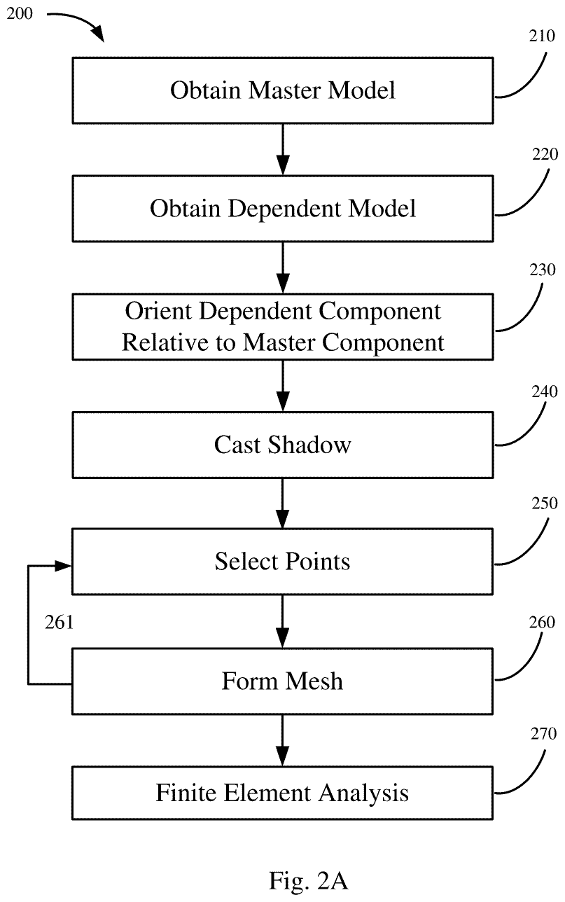

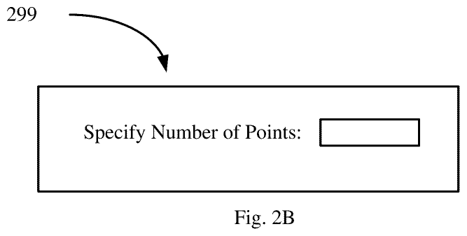

FIG. 2A is a flowchart of an embodiment of a method 200 for performing a finite element analysis of a digital model of an interface between a master component and a dependent component of a physical apparatus. The embodiment of FIG. 2A may be considered to cast a shadow 610 directly onto the surface 512 of the master component 510.

Step 210 includes obtaining a CAD model of the master component.

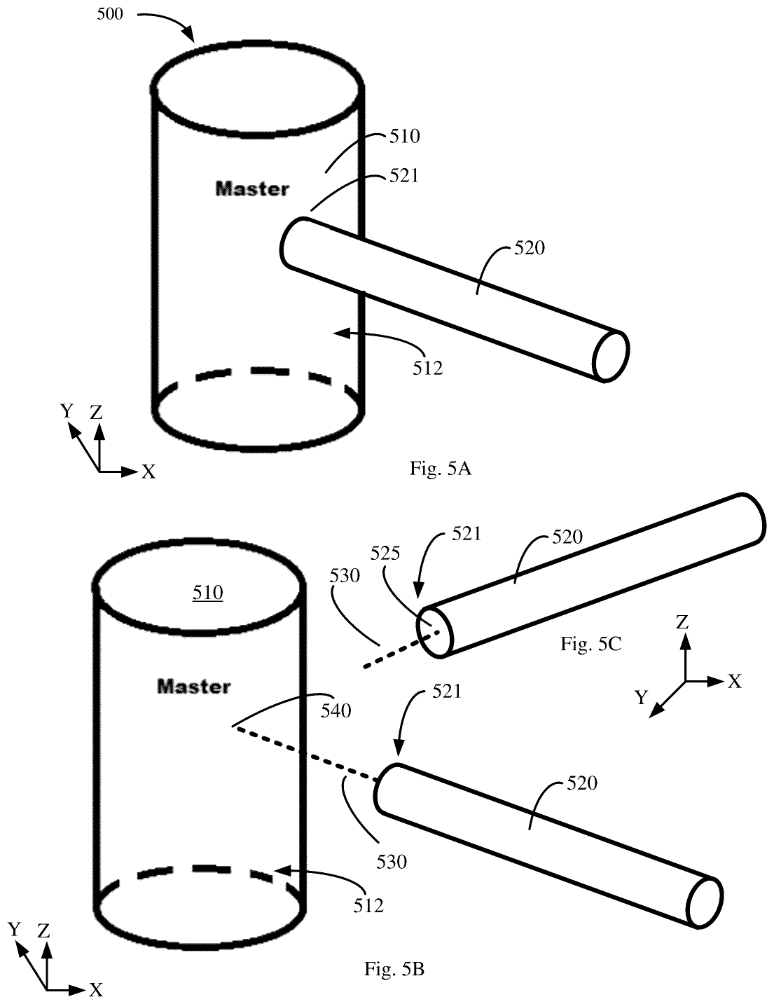

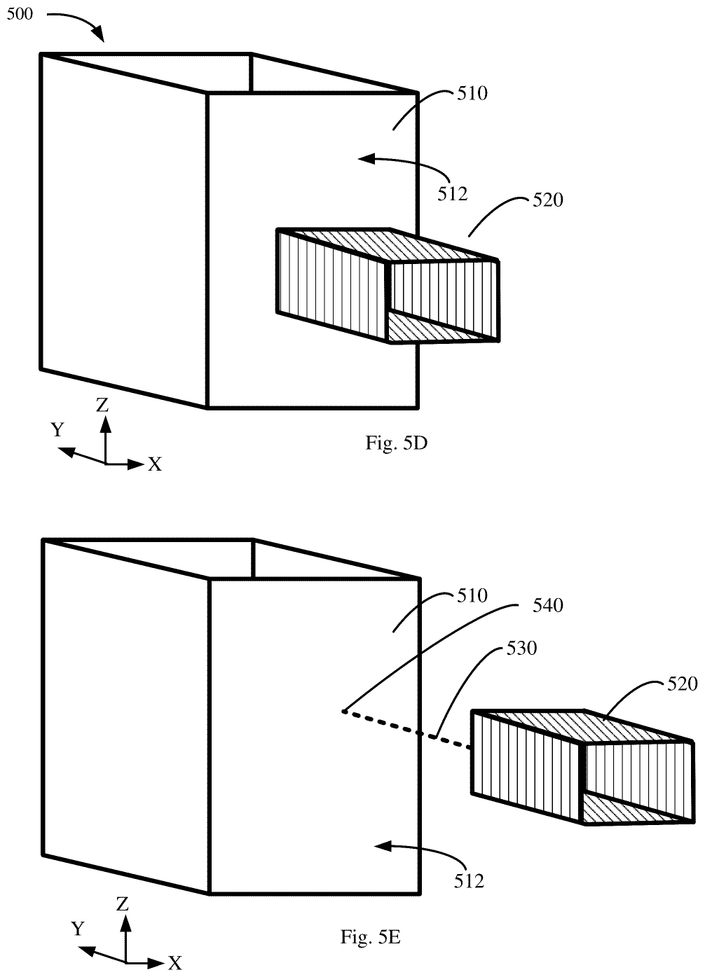

An illustrative example of a master component 510 and a dependent component 520 are schematically illustrated in FIG. 5A, FIG. 5B and FIG. 5C. An illustrative example of another master component 510 and another dependent component 520 are schematically illustrated in FIG. 5D, FIG. 5E.

In illustrative embodiments, the master component 510 has a master surface 512 and an interface point 540 at which interface point 540 the dependent component 520 meets the master component 510. In such embodiments, the dependent component 520 has an interface area (or interface end) 521 at which the dependent component 520 meets the surface 512 of the master component 510. In illustrative embodiments, the interface area 521 defines an interface plane 525. The interface plane 525 defines a longitudinal axis 530 normal to the interface plane 525. In some embodiments, the system 100 displays the longitudinal axis on the computer screen 104.

Step 230 includes orienting, in a CAD environment, the model of the dependent component 520 relative to the model of the master component 510. Such orienting may be referred-to as orienting the dependent component 520 relative to the master component 510. In illustrative embodiments, orienting the dependent component 520 relative to the master component 510 includes displaying a point of intersection 540 where the longitudinal axis 530 of dependent component 520 meets the surface 512 of the master component 510.

Step 240 includes casting, in the CAD environment, a shadow 610 of the interface plane 525 onto the surface 512 of the master component 510. The shadow 610 has a contour at its outer edge 611, which contour depends in part on the shape of the interface plane 525 and the shape (or contour) of the surface 512 of the master component 510.

Typical CAD systems have the ability to cast a shadow of an element of a CAD drawing, such as from a virtual light source 550. In preferred embodiments, the shadow 610 is cast using light rays (e.g., from the virtual light source 550) that are parallel to one another. In some embodiments, the shadow 610 is cast using light rays (e.g., from the virtual light source 550) that are not parallel to one another, but preferably have a small angle relative to one another. In some such embodiments, the angle between such non-parallel light rays may be 1 degree, between one degree and two degrees, 2 degrees, between 2 degrees and 3 degrees, 3 degrees, between 4 degrees and 5 degrees, or 5 degrees. In some embodiments, such angle between virtual light rays may depend, for example, on the way in which the virtual light source 550 generates the light rays. In some embodiments, such angle between virtual light rays may depend, for example, on how far the virtual light source is, in the CAD drawing, from the interface plane 525 of the dependent component 520. In general, a greater distance between the virtual light source 550 and the interface plane 525 is preferred over a smaller distance because virtual light ray impinging on the interface plane 525 of the dependent component tend to be more nearly parallel to one another (i.e., have a smaller angle relative to one another) with greater distance.

Step 250 includes selecting points from the shadow 610, which points will form the basis of a mesh for finite element analysis.

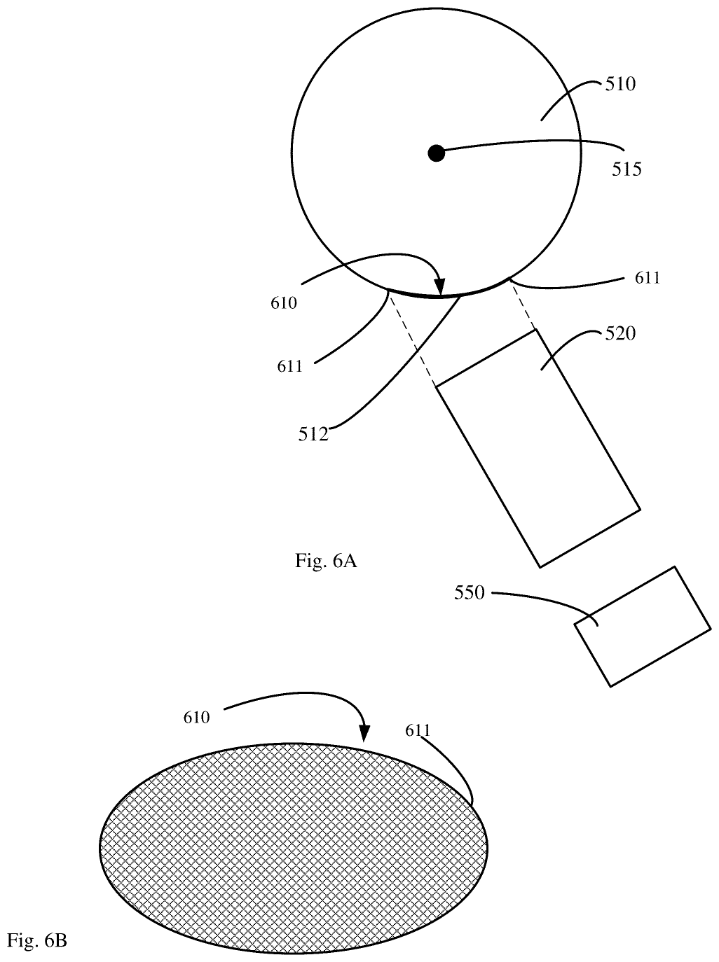

In illustrative embodiments, step 250 includes identifying a first group of points on the edge 611 of the shadow 610, as schematically illustrated in FIG. 6A and FIG. 6B, for example. That first group of points includes a plurality of points forming the contour of the shadow 610.

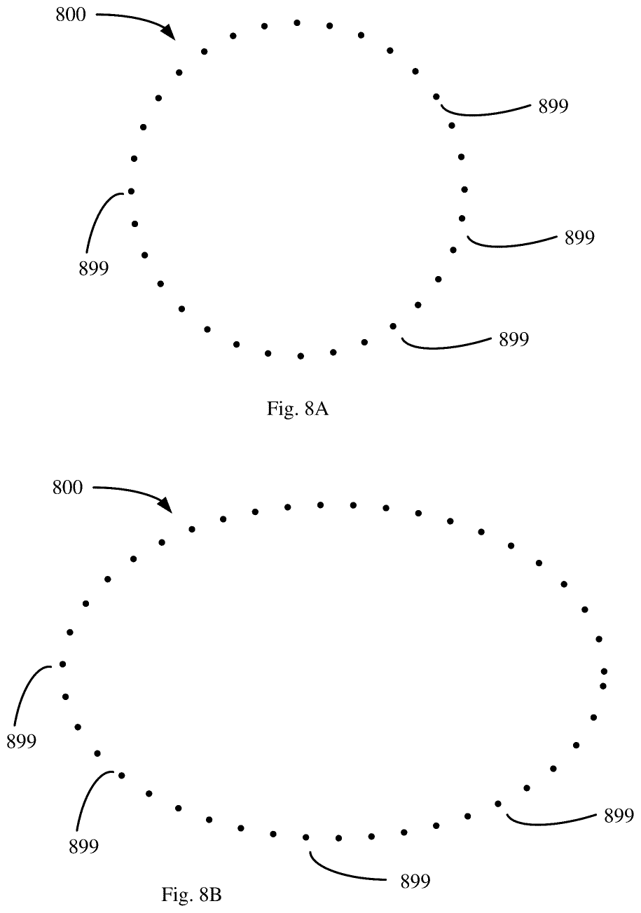

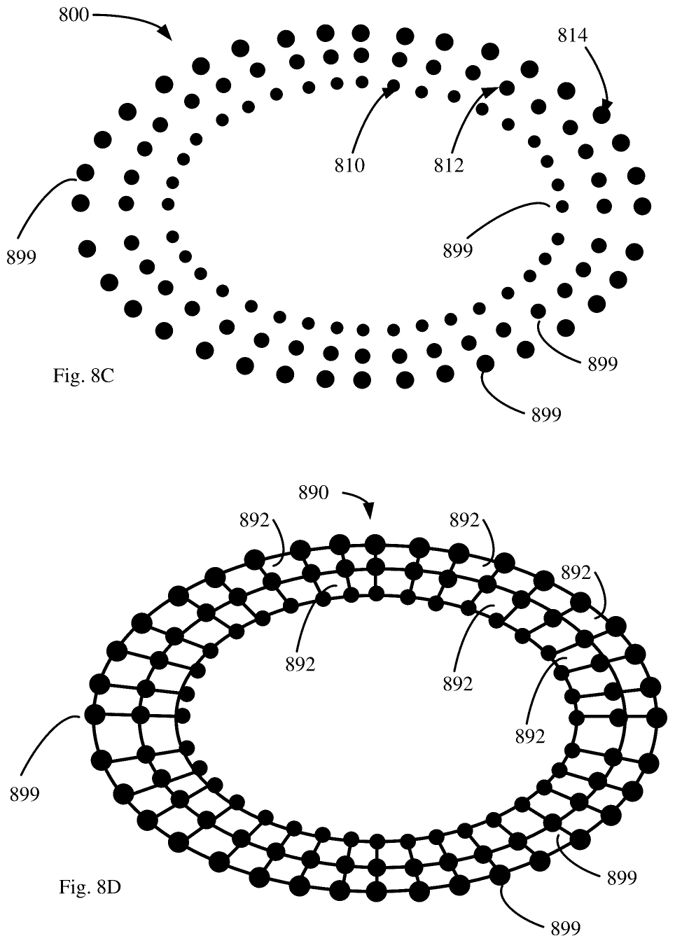

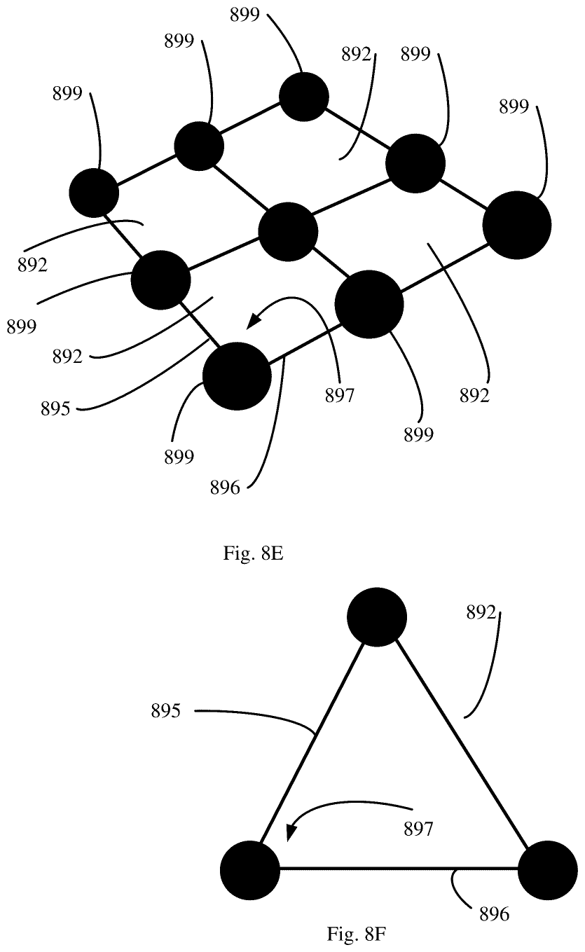

An embodiment of a first group of points 800 is schematically illustrated in FIG. 8A. The contour of the first group of points 800 in FIG. 8A forms a circle, such as would have been derived from a circular shadow, such as a shadow cased on a planar surface by a dependent component 520 having a circular cross-section.

Another embodiment of a first group of points 800 is schematically illustrated in FIG. 8B. The contour of the first group of points 800 in FIG. 8B forms an ellipse, such as would have been derived from an elliptical shadow, such as a shadow cased on a planar surface by a dependent component 520 having a circular cross-section an having a longitudinal axis 530 that intersects a planar surface 512 of a primary component 510, or a shadow plane 620, at an angle that is not a right angle.

Step 250 also includes identifying at least one a second group of points of the shadow, each such second group points including a plurality of points 899 surrounding the first group of points. In illustrative embodiments, step 250 includes identifying a plurality of second groups of points, each such group forming a path around the first group of points. In illustrative embodiments, each second group of points is concentric with the first group of points. In some embodiments in which the shadow 610 is cast directly on the surface 512 of the first component 510, the first group of points and the second group of points may be considered to be coincident with corresponding points on the surface 512 of the first component 510.

An illustrative embodiment of a second group of points 810 is schematically illustrated in FIG. 8C. In this embodiment, the second group of points 810 forms an ellipse, and is concentric with (i.e., has the same center point as) the first group of points 810.

FIG. 8C also schematically illustrates an additional second group of points 812, and a third second group of points, 814.

In some embodiments a system operator may identify the points based on user experience, for example via a user interface 299 generated by and presented on a computer monitor of a CAD system 100, as schematically illustrated in FIG. 2B. In some embodiments, a system operator may identify a portion of the CAD drawing, and may specify how may points should be identified in within that portion and the CAD system 100 (e.g., a points module 170) automatically identifies the points based on that operator input. In some embodiments, a system operator may specify a distance between adjacent points, and the CAD system 100 (e.g., a points module 170) automatically identifies the points based on that operator input. In some embodiments, methods and systems start with a default number of points on each group of points and then automatically assess the respective aspect ratios of the resulting mesh elements 892 (as described below) to determine whether to repeat step 250 to identify additional points. In illustrative embodiments, the default number of points may be 12 points, for example. In some embodiments, the default number of points may be 20 points, a number of points not less than 20 points but less than 30 points; 30 points, a number of points not less than 30 points but less than 40 points, 40 points, a number of points not less than 40 points but less than 50 points, 50 points, a number of points not less than 50 points but less than 50 points, 100 points, a number of points not less than 100 points but less than 200 points, to name but a few examples.

As described below, the points are used to form a plurality of mesh elements 892, as schematically illustrated in FIG. 8D and FIG. 8E. In some embodiments, the number of points is selected, specified or determined so that each mesh element 892 has an aspect ratio of equal to or less than 4:1, where the aspect ratio of a mesh element 892 is defined as the ratio of the length of the mesh element to the width of the mesh element. For example, in FIG. 8E, one mesh element 892 has a first side 895 representing the length of the mesh element 892, and a second side 896 representing the width of the mesh element 892, where the first side 895 is immediately adjacent to the second side, and the first side 895 has a length that is equal to or greater than the length of the second side 896. For example, if the first side 895 has a length of 1.7 millimeters, and the second side 896 has a length of 0.8 millimeters, the aspect ratio of the mesh element would be 1.7 divided by 0.8, which equals a ratio of 2.125, which is less than 4:1. As another example, if the first side 895 has a length of 4.0 millimeters, and the second side 896 has a length of 1.7 millimeters, the aspect ratio of the mesh element would be 4.0 divided by 1.7, which equals a ratio of 2.35, which is less than 4:1. In illustrative embodiments, if the aspect ratio of any mesh element of the plurality of mesh elements is greater than 4:1, then the number of points is insufficient, and the operator, or the system, may increase the number of points until the aspect ratio of each mesh element 892 is equal to or less than 4.0. In general, the more mesh elements used for finite element analysis, the more accurate the results of the finite element analysis. Although examples herein are described with reference to an aspect ratio of less than or equal to 4:1, other embodiments may use a different aspect ratio. For example, depending on the structure being subject to finite element analysis and the experience level of the system operator, some embodiments may specify or require an a different pre-specified aspect ratio, such as an aspect ratio of less than or equal to 1:1; less than or equal to 2:1; less than or equal to 3:1; less than or equal to 5:1; less than or equal to 6:1; less than or equal to 7:1; or less than or equal to 8:1. Some embodiments include a user interface configured to receive, from a user, specification of the number of points. An illustrative embodiment of such a user interface is schematically illustrated in FIG. 2B.

In illustrative embodiments using a four-noded mesh element 892, the interior angle 897 between any two adjacent sides 895, 896 of the mesh element 892 is preferably ninety degrees (90 degrees), or within 60 degrees of a right angle (e.g., ninety degrees plus or minus 60 degrees). The interior angle 897 between any two adjacent sides 895, 896 of the mesh element 892 should not be less than 30 degrees.

In illustrative embodiments, no four-noded mesh element 892 of a mesh 890 is a “twisted” element, in that no such mesh element 892 has two sides that cross each other (e.g., to make an “X” pattern).

FIG. 8F schematically illustrates a triangular (or three-sided) mesh element 892. In illustrative embodiments, the aspect ratio of a triangular mesh element 892 is defined as the ratio of the length of the longest side (or leg) 895 of the triangular mesh element 892 to the length of the shortest side (or leg) 896 of the mesh element 892. In illustrative embodiments, aspect ratio of each triangular mesh element 892 is equal to or less than 4.0.

In illustrative embodiments using a triangular mesh element 892, the interior angle 897 between any two adjacent sides 895, 896 of the mesh element 892 is not less than 30 degrees.

Step 260 includes forming a mesh 890 from the identified points (i.e., points identified at step 250), which mesh includes a plurality of mesh elements 892. This may be done automatically by the CAD system 100, such as by a mesh module 180. In illustrative embodiments, each mesh element is defined by four of the identified points, and may be referred-to as a four-noded mesh element or a “quadrilateral” mesh element. A mesh of four-noded mesh elements may be referred-to as a four-noded mesh. A four-noded mesh 890 is schematically illustrated in FIG. 8D, for example.

In preferred embodiments, each mesh element shares at least one node (i.e., one of the identified points) in common with an adjacent mesh element, and no node is part of only a single mesh element. Note that a mesh generated for generating an image, such as in computer animation, video games, and even a conventional CAD drawing, etc., is not sufficient to serve as a mesh generated by step 260, and is not sufficient for use as input for finite element analysis, because in those applications, a gap between mesh elements is acceptable in that any lack of fidelity in the rendered image will not degrade the image (relative to an image rendered from a mesh in which there are no gaps between adjacent mesh elements) to the point that a human eye would notice the degradation.

In illustrative embodiments, each mesh element 892 has an aspect ratio of less than or equal to 4:1, as described above. Some embodiments determine which mesh element 892 of the plurality of mesh elements has the largest aspect ratio, and if the aspect ratio of that mesh element is greater than 4:1, then the method loops back (step 261) to step 250 and increases the number of identified points and repeats step 260 until each mesh element 892 has an aspect ratio of less than or equal to 4:1 (i.e., an aspect ratio not greater than 4:1).

Step 270 includes performing finite element analysis of the multi-component object 500 based on the mesh 890 generated at step 260. The mesh 890 is input to, and used by, a finite element analysis engine (e.g., finite element analysis module 190).

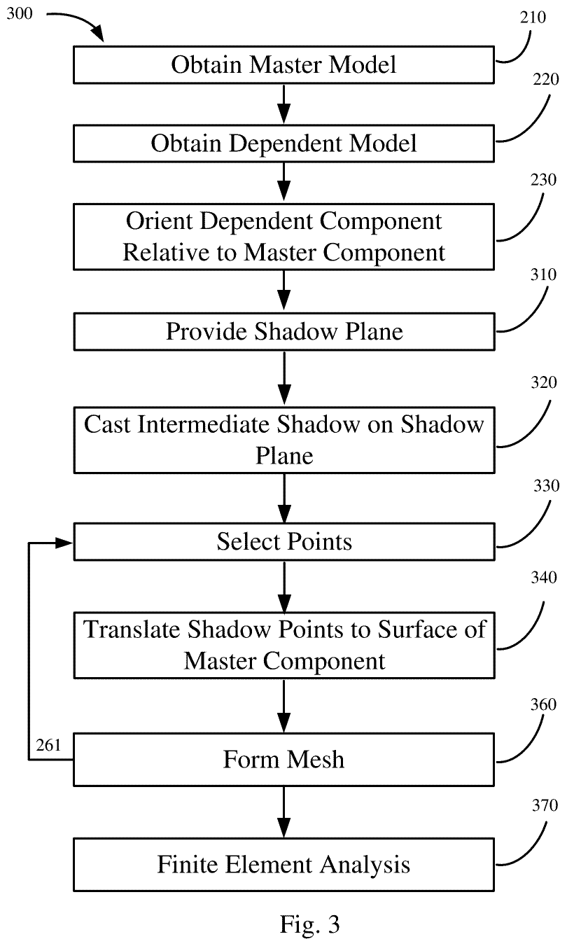

FIG. 3 is a flowchart of an embodiment of a method 300 for performing a finite element analysis of a digital model of an interface between a master component and a dependent component of a physical apparatus. The embodiment of FIG. 3 may be considered to cast a shadow 610 indirectly onto the surface 512 of the master component 510 because the method 300 includes casting an intermediate shadow 630 on a shadow plane 260 (rather than casting the shadow directly on the surface 512 master component 510), and then translating points from the intermediate shadow 630 onto the surface 512 master component 510.

In the method 300, step 210, step 220, step 230, step 260 and step 270 are the same as described above for method 200.

Rather than cast a shadow 610 directly onto the surface 512 master component 510, however, method 300 (after step 210, step 220 and step 230) provides a shadow plane 620 at step 310.

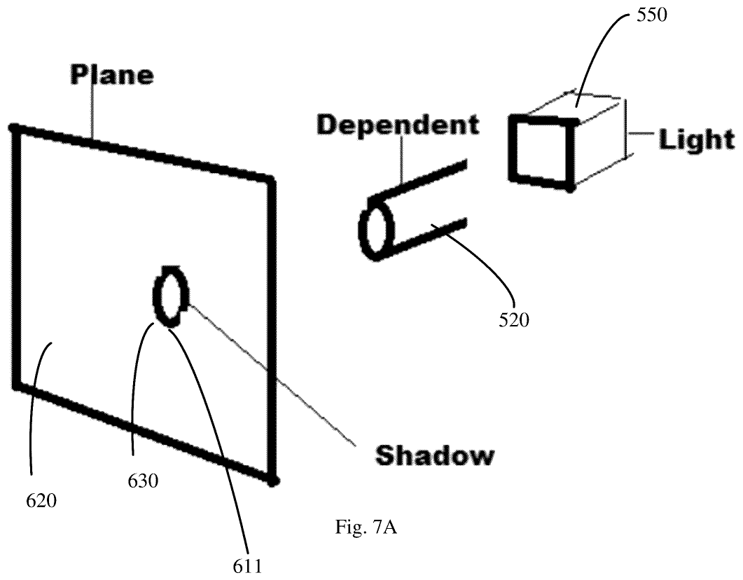

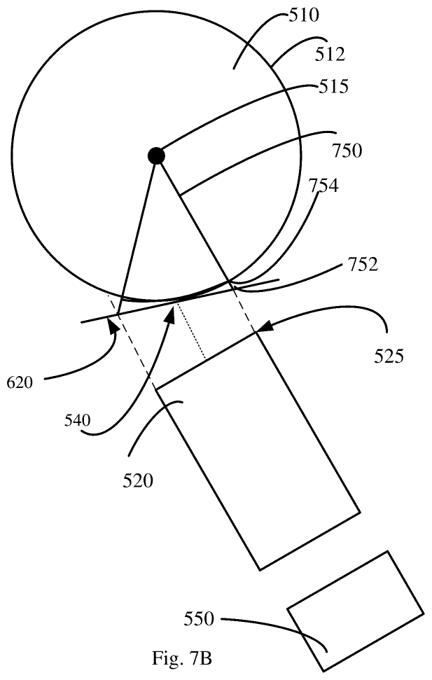

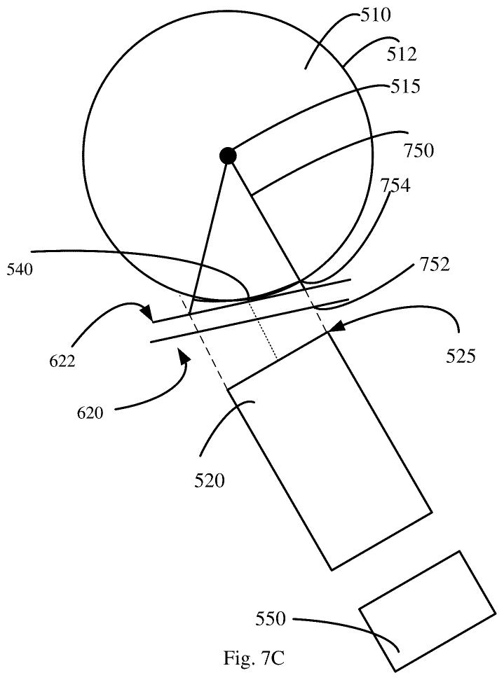

In illustrative embodiments, the shadow plane is parallel to a tangent plane 622, which tangent plane 622 is tangent to the master surface 512 at the point of intersection 540 where the dependent component 520 intersects the master surface 512. In some embodiments, the shadow plane 620 is co-planar with the tangent plane 622, as schematically illustrated in FIG. 7B.

In some embodiments, the shadow plane 620 is not co-planar with the tangent plane 622, and is disposed between the tangent plane 622 (e.g., between the point of intersection 540) and the dependent component 520, as schematically illustrated in FIG. 7C (such a shadow plane may be referred-to as a “floating” plane). In some embodiments, the master surface 512 comprises a flat surface defining a two-dimensional plane, and that flat surface is the two-dimensional shadow plane.

The method 300 then casts an intermediate shadow 630 on the shadow plane 620 at step 320. An embodiment of a shadow plane 620 and an embodiment of an intermediate shadow 630 are schematically illustrated in FIG. 7A. In preferred embodiments, the intermediate shadow 630 is cast using light rays (e.g., from the virtual light source 550) that are parallel to one another. In some embodiments, the intermediate shadow 630 is cast using light rays (e.g., from the virtual light source 550) that are not parallel to one another, but preferably have a small angle relative to one another. In some such embodiments, the angle between such non-parallel light rays may be 1 degree, between one degree and two degrees, 2 degrees, between 2 degrees and 3 degrees, 3 degrees, between 4 degrees and 5 degrees, or 5 degrees. In some embodiments, such angle between virtual light rays may depend, for example, on the way in which the virtual light source 550 generates the light rays. In some embodiments, such angle between virtual light rays may depend, for example, on how far the virtual light source is, in the CAD drawing, from the interface plane 525 of the dependent component 520. In general, a greater distance between the virtual light source and the interface plane 525 is preferred to a smaller distance because virtual light ray impinging on the interface plane 525 of the dependent component tend to be more nearly parallel to one another (i.e., have a smaller angle relative to one another) with greater distance.

At step 330, subsequent to step 320, the method 300 selects points on the shadow plane 620 from the intermediate shadow 630. In illustrative embodiments, step 330 includes identifying a first group of points on the edge 611 of the intermediate shadow 630. That first group of points includes a plurality of points forming the contour of the intermediate shadow 630. In illustrative embodiment, the points of said first group of points are selected to be spaced apart from one another, so that the first group of points does not form a continuous curve. In some illustrative embodiments, the spacing between the points of the first group of points is specified by a CAD operator. In some illustrative embodiments, the spacing between the points of the first group of points is determined as a fraction of the circumference of the dependent component 520, where the “circumference” is the total distance around the outside surface of the dependent component 520. For example, in some embodiments, the spacing between the points of the first group of points is set at one percent (1%) of the circumference of the dependent component 520. In some embodiments, the spacing between the points of the first group of points is set at one-half percent (0.5%) of the circumference, or one quarter (0.25%), or two percent (2%), of the circumference of the dependent component 520.

Step 330 also includes identifying at least one second group of points of the intermediate shadow 630 (and in some embodiments, includes identifying a plurality of such second groups of points), each such second group points including a plurality of points surrounding the first group of points. In illustrative embodiments, step 330 includes identifying a plurality of second groups of points, each such group forming a path around the first group of points. In illustrative embodiments, each second group of points is concentric with the first group of points.

In some embodiments, one or more of such second group of points is selected so that the points are disposed within (i.e., are surrounded by) the first group of points.

Each point identified in step 330 may be referred-to as a shadow point.

Subsequent to step 330, step 340 translates the shadow points identified at step 330 from the shadow plain 620 to the surface 512 of the master component 510.

In the case in which the master surface 512 is planar, the act of translating shadow points from the shadow plain 620 to the surface 512 of the master component 510 includes simply projecting each point from the shadow plane 620 to the master surface 512 along a line normal to the shadow plane 620.

In the case where the master component 510 has a surface 512 that is curved (for example, with a constant radius such as when the master component 510 has a circular cross-section), step 340 translates the points identified at step 330 from the intermediate shadow 630 to the surface 512 of the master component 510 by identifying a reference point 515 internal to the master component 510. In illustrative embodiments, the reference point 515 is at the geometric center of the cross-section of the master component 510. For example, in FIG. 7B, the master component 510 has a circular cross-section, and a reference point 515 at the center of the circular cross section.

Then, for each shadow point identified at step 330, step 340 identifies a corresponding mesh node point on the surface 512 of the master component 510 as a point on the surface 512 of the master component 510 at which a line segment between a shadow point identified at step 330 and said reference point crosses the surface 512 of the master component.

For example, in FIG. 7B, the method 300, and system 100, defines a line segment 750 extending from the reference point 515 to a shadow point 752 on the shadow plane. The corresponding mesh node point 754 lies at the intersection. Step 340 thereby identifies one mesh node point on the surface 512 of the primary component 510 for (and corresponding to) each shadow point on the shadow plane 620.

The mesh nodes on the surface 512 of the primary component 510 form a contour that is similar to, but in illustrative embodiments is not identical to, the intermediate shadow 630. For example, in circumstances in which the surface 512 of the primary component 510 is curved, the curve of the surface will result in the contour of the mesh node points being a distorted (differently-shaped) version of the intermediate shadow 630.

Moreover, at step 340, each mesh node point is, relative to its corresponding intermediate shadow point, biased towards the longitudinal axis 530. As a consequence, the contour of the mesh node points on the surface 512 of the primary component 510 is smaller than the intermediate shadow 630. The contour of the mesh node points on the surface 512 of the primary component 510 may be beneficial in that it identified mesh node points that are closer to the longitudinal axis 530, and therefore closer to the center of the dependent component 520. This could be beneficial, for example, when the dependent component 520 is a duct, pipe or cylinder having walls with unknown thickness, or when the dependent component 520 is a solid cylinder. In such cases, at least some of the mesh node points represent points within the duct walls, pipe walls, and/or in the interior of the cylinder, which points might otherwise have been omitted from a mesh and finite element analysis, as described herein.

Subsequent to step 340, the method 300 forms a mesh at step 360, and performs finite element analysis, using the mesh as input, at step 370, as described above in connection with steps 260 and step 270, respectively, of method 200.

In illustrative embodiments, each mesh element 892 has an aspect ratio of less than or equal to 4:1, as described above. Some embodiments determine which mesh element 892 of the plurality of mesh elements has the largest aspect ratio, and if the aspect ratio of that mesh element is greater than 4:1, then the method loops back (step 261) to step 330 and increases the number of shadow points and repeat steps 330 and step 260 until each mesh element 892 has an aspect ratio of less than or equal to 4:1 (i.e., an aspect ratio not greater than 4:1).

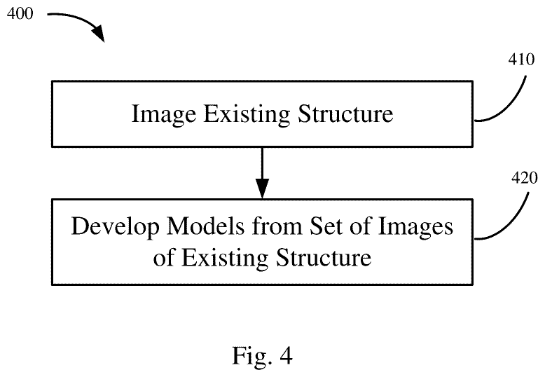

FIG. 4 is a flowchart of an embodiment of a method for modeling an existing (i.e., already-constructed) multi-component structure.

Step 410 includes scanning the existing multi-component system with a scanning modality to create an image set of one or more images of the system, such as a scanning apparatus that produces a set of one or more photographs of the system, or a point cloud of the system. In illustrative embodiments, the set of images includes an image of at least a portion of the primary component, at least a portion of the dependent component, and an image of the intersection of the dependent component with the primary component. In some embodiments, the scanning modality includes flyable drone, which drone can create the set of images under control of a drone operator.

Step 420 includes generating a CAD model of the master component 510 and a CAD model of the dependent component 520 from the set of images of the system produced by the scanning modality. In some embodiments, such models are created by a CAD operator, based on the CAD operator's observation of the image set. In some embodiments, such models are created by an artificial intelligence agent, which artificial intelligence agent may be implemented by an artificial intelligence module 141 of system 100. Such an artificial intelligence agent is trained to recognize system components based on a training set of images. Such components may be, for example, pipes, tubes, tanks, struts, and beams, to name but a few examples, and the training set includes images of such components. The CAD model generated in this way is then employed as input to the methods and systems described herein. The artificial intelligence module 141 may include a mesh-generating artificial intelligence configured to generate a mesh at or around an interface 523 of a master component 510 and a dependent component 520, as described herein.

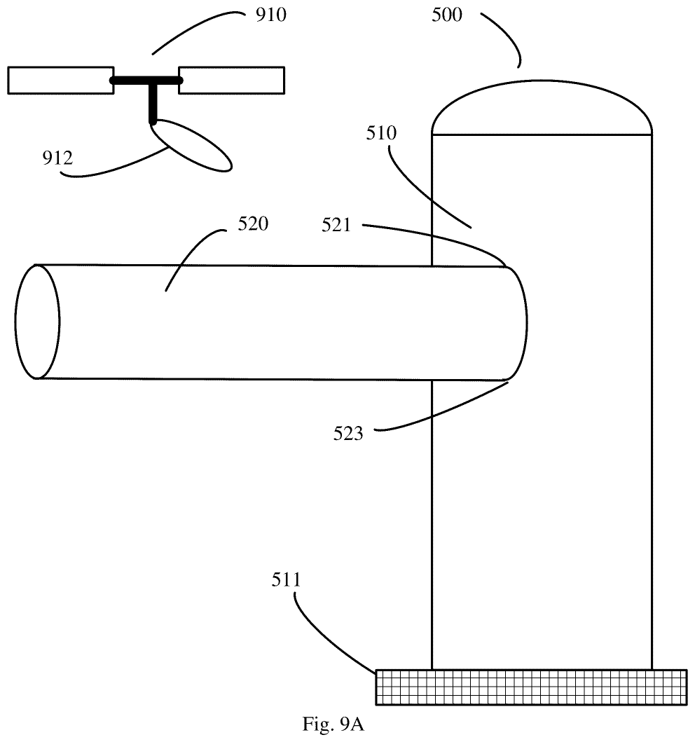

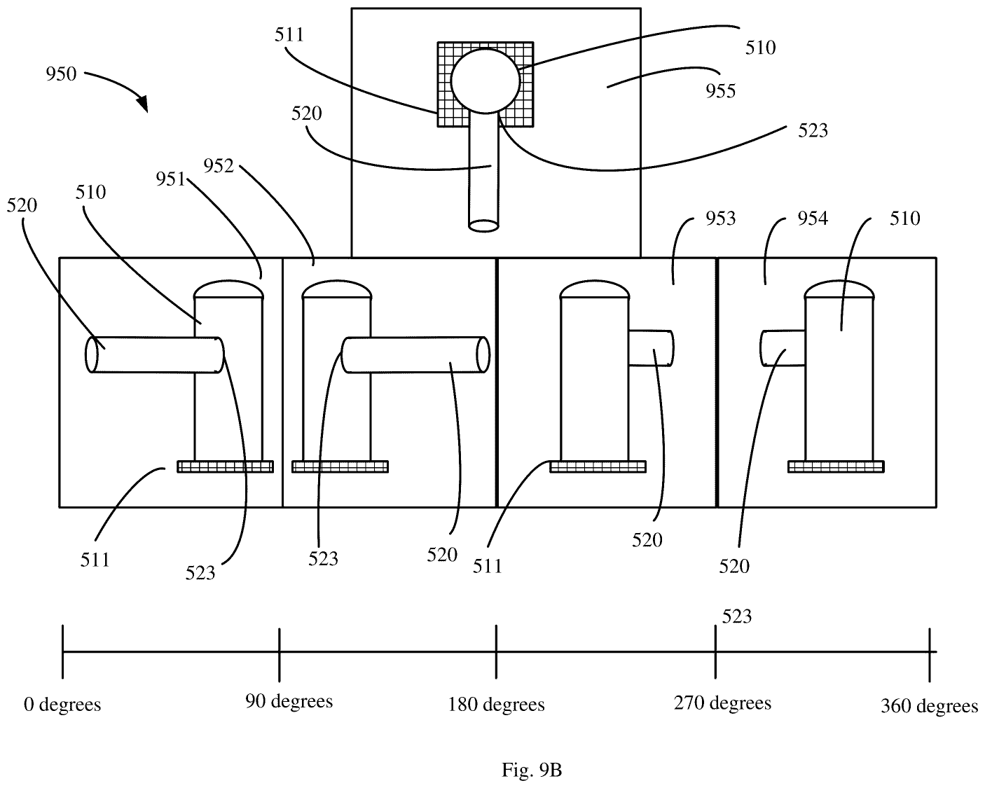

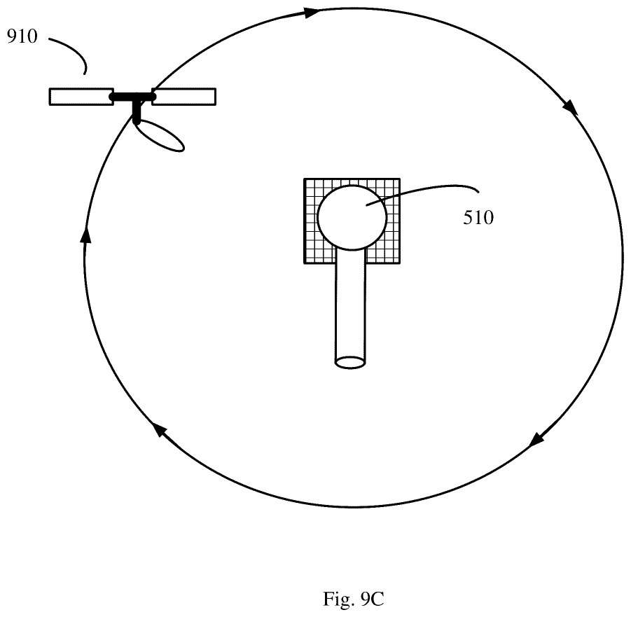

FIG. 9A schematically illustrates an embodiment of a drone 910 flying near, and imaging (e.g., photographing_, a multi-component system 500. The drone 910 may be, for example, a Leica BLK2FLY autonomous flying laser scanner available from Leica Geosystems.

The drone 910 has a drone imaging device 912 positioned such that the drone imaging device 912 is disposed to acquire images of the multi-component system 500 when the drone 910 flies near the multi-component system 500. The drone imaging device 912 may be, for example, a BLK360 Scanner available from Leica Geosystems.

In some embodiments, the drone 910 includes a system 100 to process images of the multi-component system 500 acquired by the drone imaging devices 912. In some embodiments, the drone 910 includes a communications interface to transmit to a CAD system 100 images of the multi-component system 500 acquired by the drone camera 912.

FIG. 9B schematically illustrates an embodiment of a compiled set 950 of images (951; 952; 953; 954) of a multi-component system. The images (951; 952; 953; 954) in the compiled set 950 may include images taken by a drone 910, for example. Some embodiments include a top image 955 (i.e., an image looking down at the top of the system 500.

The images 951; 952; 953; 954, 955 of the compiled set 950 show the master component 510 and dependent component 520 of the previously-constructed system 500, and the interface 523 of the master component 510 and dependent component 520 from a plurality of angles or points of view. Collectively, the images 951; 952; 953; 954 in the compiled set 950 provide a complete (e.g., 360 degree) view the interface 523 of the master component 510 and dependent component 520.

In some embodiments, the images of the compiled set 950 provide a less than 360 degree view the interface 523 of the master component 510 and dependent component 520. For example, in some embodiments, the images of the compiled set 950 provide a 180 degree view the interface 523 of the master component 510 and dependent component 520.

In some embodiments, the images of the compiled set 950 provide a view the interface 523 of the master component 510 and dependent component 520 that is between 180 degrees and 360 degrees.

In illustrative embodiments, the images 951; 952; 953; 954 (and 955, in embodiments that include a top image) are arranged in a pre-defined (or “previously-defined) pattern to form the compiled set. Such a compiled set may be referred-to as a collage. For example, in FIG. 9B, the pre-defined pattern includes four images 951, 952, 953, and 954 disposed in a linear sequence, one next to another, in which the sequence shows a corresponding plurality of view of the previously-constructed system 500, each image showing the previously-constructed system 500 from a different angle. For example, in FIG. 9B, image 951 shows the previously-constructed system 500 from an angle of 0 degrees to 90 degrees; image 952 shows the previously-constructed system 500 from an angle of 90 degrees to 180 degrees; image 953 shows the previously-constructed system 500 from an angle of 180 degrees to 270 degrees; and image 954 shows the previously-constructed system 500 from an angle of 270 degrees to 360 degrees. Some embodiments also include in image 955 of a top view of the previously-constructed system, in which the previously-defined patter includes that image disposed above the linear sequence, straddling image 952 and 953.

A collage 950 may be provided as input (and may be referred-to as in input collage) to an image-to-image generative artificial intelligence, which image-to-image generative artificial intelligence (e.g., a conditional GAN; a variational autoencoder) is trained (or “configured”) to produce an output image from the input collage 950, such as a CAD drawing of the previously-constructed multi-component system 500, or a finite element analysis drawing, comprising a mesh, of the previously-constructed multi-component system 500. Such an image-to-image generative artificial intelligence could be trained by applying to a neural network a plurality of training collages of one or more previously-constructed multi-component systems 500, wherein each such training collage include a plurality of images of a corresponding previously-constructed multi-component systems 500, the image arranged in the pre-defined pattern corresponding to the pre-defined pattern of input collage 950 for which the artificial intelligence is being trained.

FIG. 9C schematically illustrates an embodiment of a drone 910 circumnavigating a previously-constructed system 500 to photograph the previously-constructed system 500.

In some embodiments, the drone 910 circumnavigating a previously-constructed system 500 captures a set of photographs such as the plurality of photographs of the previously-constructed system 500, as described in connection with FIG. 9B.

In some embodiments, the drone 910 circumnavigating a previously-constructed system 500 captures a set of photographs, which set includes one or more panoramic images (each a “panorama”) of the previously-constructed system 500. In some embodiments, each such panorama is an outer-cylinder panorama.

A set of panoramas may be provided as input (and may be referred-to as in input panoramas) to an image-to-image generative artificial intelligence, which image-to-image generative artificial intelligence (e.g., a conditional GAN; a variational autoencoder) is trained (or “configured”) to produce an output image from the set of input panoramas, such as a CAD drawing of the previously-constructed multi-component system 500, or a finite element analysis drawing, comprising a mesh, of the previously-constructed multi-component system 500. Such an image-to-image generative artificial intelligence could be trained by applying to a neural network a plurality of training panoramas of one or more previously-constructed multi-component systems 500, wherein each such training panorama includes a panoramic image of a corresponding previously-constructed multi-component systems 500.

A. Creating a Mesh from Images

Some embodiments create a mesh suitable for finite element analysis directly from images of a previously-constructed multi-component system 500.

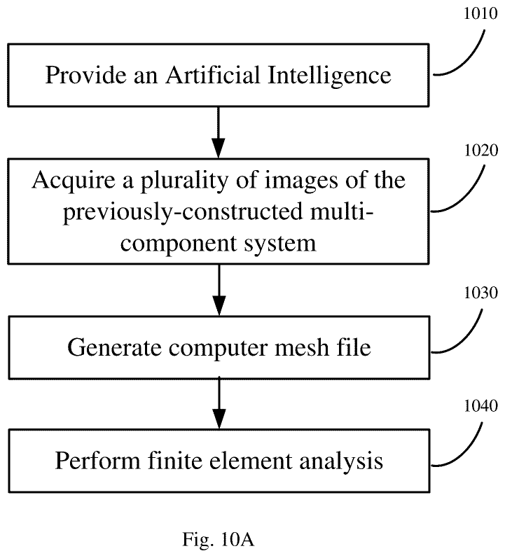

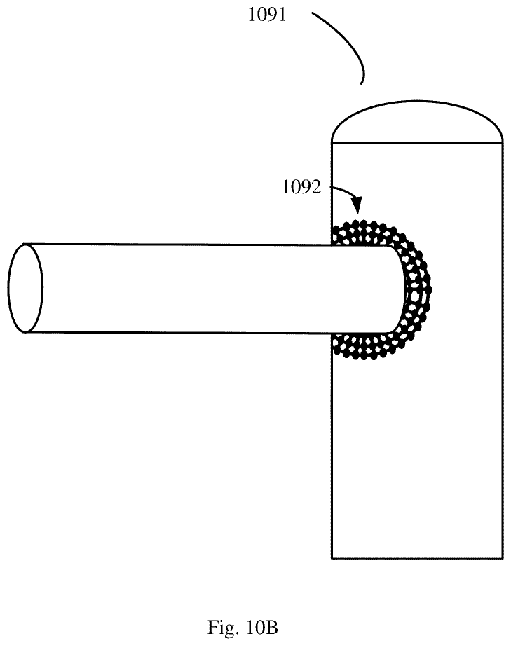

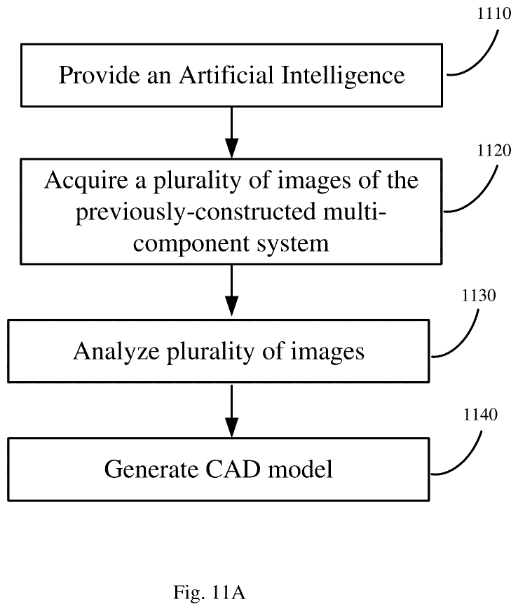

FIG. 10A is a flowchart of an embodiment of a method using artificial intelligence to generate create a mesh suitable for finite element analysis directly from images of a previously-constructed multi-component system. FIG. 10B schematically illustrates a model 1091 of a previously-constructed system and an associated mesh 1092.

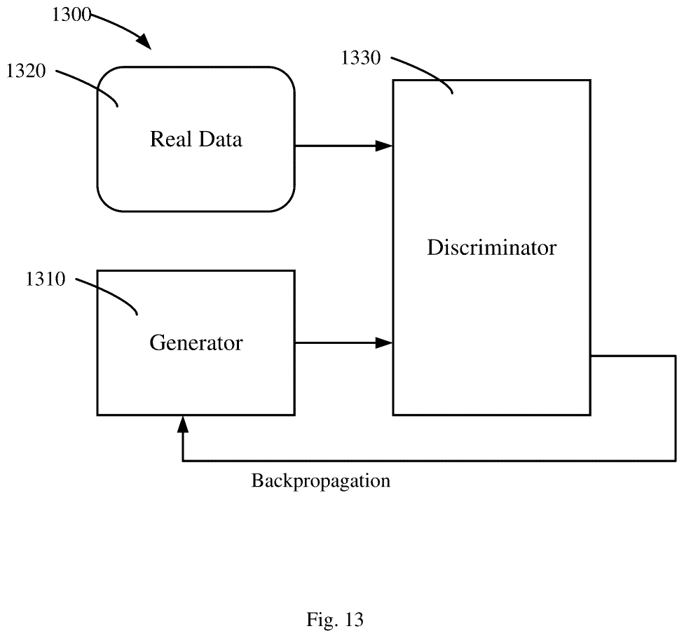

In one embodiment, the generative artificial intelligence is trained using a Generative Adversarial Network (“GAN”; which may be a conditional GAN), which is a network configured to train a artificial intelligence generator to generate an output image from an input image. A Generative Adversarial Network 1300 is schematically illustrated in FIG. 13.

The Generative Adversarial Network 1300 includes a generator 1310 configured to be trained to generate an output image from an input image (e.g., a collage). The generator 1310 may be an artificial deep neural network having several layers of nodes, including an input node layer, an output node layer, and a plurality of hidden layers disposed between the input node layer and the output node layer.

When trained, the generator 1310 is configured to generate (e.g., produce) an output image from an input image. In some embodiments, the input image may include an input collage of component images arranged relative to one another in a pre-defined configuration. For example, the plurality of images in the input collage may each show an object from a corresponding plurality of viewpoints, such that each image shows the object from an associated viewpoint. Collectively, the plurality of images of the input collage show the object more completely than any single one of the images.

In some embodiments, the images of the input collage collectively show the object from 360 degrees around the object.

In some embodiments, the images of the collage collectively show each side surface of the object. In some embodiments, the images of the collage also show the object from a viewpoint above the object (i.e., such images show the top of the object). In some embodiments, the images of the input collage also show the object from a viewpoint below the object (i.e., such images show the bottom of the object).

The Generative Adversarial Network 1300 includes a source of training images 1320, which source 1320 holds a set of training images. The number of training images in the set of training images may be as few as two thousand or three thousand images, or could be ten thousand or twenty thousand images or one hundred thousand images, depending on the complexity of the object in the images and the quality of images for which the image generator 1310 is being trained. In some embodiments, each training image of the set of training images comprises a training collage of component images of an object (e.g., the previously-constructed system), the component images arranged relative to one another in a pre-defined configuration, which pre-defined configuration matches the pre-defined configuration of the input images of an input collage for which the generator 1310 is being trained. For example, the plurality of images in the training collage may each show an object from a corresponding plurality of viewpoints, such that each image shows the object from an associated viewpoint. Collectively, the plurality of images of the training collage show the object more completely than any single image.

In some embodiments, the images of the training collage collectively show the object from 360 degrees around the object.

In some embodiments, the images of the training collage collectively show each side surface of the object. In some embodiments, the images of the training collage also show the object from a viewpoint above the object (i.e., such images show the top of the object). In some embodiments, the images of the training collage also show the object from a viewpoint below the object (i.e., such images show the bottom of the object).

In some embodiments, each training image of the set of training images comprises a panorama of the object (e.g., the previously-constructed system).

The Generative Adversarial Network 1300 includes a discriminator 1330. The discriminator 1330 is an artificial neural network. In some embodiments, the discriminator 1330 may include a convolutional neural network having a plurality of layers, including an input layer, an output layer, and a set of intervening layers include a set of convolutional layers.

The discriminator 1330 is configured (i.e., trained) to differentiate between an output image (which may be referred-to as a generated image or an artificial image) generated by the generator 1310 and a real image from the training set from the source of training images 1320.

The discriminator 1330 may be trained, for example, by supervised learning with a set of training models. For example, in some embodiments, the discriminator 1330 is trained by providing a first training set including a set of images of one or more previously-constructed structures, and training the discriminator's neural network using the first training set. Some embodiments also include providing a second training set including images that are not images of a previously-constructed structure and training the discriminator's neural network using the second training set. In some embodiments, the second training set also includes one or more images from the first training set.

In some embodiments, the Generative Adversarial Network 1300 may be Conditional Generative Adversarial Network (“cGAN”) in which both the generator 1310 and the discriminator 1330 receive, as input, conditioning information including an input image (e.g., a collage). The generator 1310 uses this conditioning information to produce a corresponding output image, and the discriminator 1330 uses the same conditioning information to evaluate the authenticity of the image generated by the generator 1310. The generator uses this conditioning information to produce a corresponding output (e.g., an image), and the discriminator uses the same conditioning information to evaluate the authenticity of the generated image.

For example, in an illustrative embodiment, the conditioning information includes one or more input images, in which each input image is a collage of photographs (or a set of panoramas) of a previously-constructed (i.e., previously-built) structure. That input image is passed as input to both the generator 1310 and the discriminator 1330.

In some embodiments, the generator 1310 receives the input image along with random noise (which may be referred-to as a “latent vector”). The noise allows the generator 1310 to add variability or randomness to the output, creating diverse results even (for example) in the case in which the same input image is given. The generator 1310 then tries to produce an output image that matches the distribution of real images corresponding to the given input.

In illustrative embodiments, the trained discriminator 1330 evaluates whether the generated image is real or fake, but in the case of a cGAN, it also checks if the generated image corresponds to the given input image properly. It tries to determine if the generated image is a realistic output for that specific input.

This training process continues until the generator 1310 can produce images that are difficult for the discriminator 1330 to distinguish from the true images related to the input.

When the generator 1310 is trained to produce an output image that is a CAD drawing, the set of training models includes CAD drawings. Such CAD drawings are not merely images of a real-world physical object, but instead are precise drawings of the object having proportions that are accurate relative to the physical object. Characteristics of an output image generated by a trained generator 1310 may include (or be defined by) one of more of the following characteristics:
The CAD drawing is scalable, allowing a CAD operator to adjust the drawing over a plurality of sizes without losing detail or accuracy.
The CAD drawing includes a plurality of layers, and each component of the object represented by the CAD drawing may reside in one of a corresponding plurality of associated layers.
The CAD drawing may be created and saved in a specific file format selected from, for example, .dwg, .dxf, or .stl. These formats are widely supported by various CAD software tools and can be shared, modified, and printed easily.
The CAD drawing may be editable using CAD software, so that changes can be made quickly.
The CAD drawing may support parametric modeling, in which elements of a design are defined by parameters (like dimensions or angles), such that when an element of the design is modified (e.g., by a CAD user), others elements of the design are adjusted automatically to maintain the integrity of the design.

When the generator 1310 is trained to produce an output image that is configured as input for finite element analysis (“FEA”), the set of training models includes drawings that include a mesh suitable for finite element analysis. Several examples of such a mesh suitable for finite element analysis are described herein.

A Generative Adversarial Network trains a generator 1310 by allowing the GAN to run over time, to perform unsupervised learning. The generator 1310 is trained by causing the generator 1310 to produce an image, and having that image evaluated by the discriminator 1330, which then provides feedback to the generator 1310. After many iterations, the generator 1310 learns to produce a CAD model of a previously-constructed structure from a set of images of the previously-constructed structure. When trained in this way, the generator 1310 of the GAN is the generative artificial intelligence.

In other embodiments, such an artificial intelligence may be trained by a variational autoencoder (“VAE”). For example, in an illustrative embodiment, a generative artificial intelligence is trained to produce a model of a previously-constructed structure by providing a large set of images to a variational autoencoder, where each image of the large set of images includes a previously-constructed structure and an associated mesh suitable for finite element analysis.

The variational autoencoder has an encoder configured to compress an image into a corresponding latent representation, and a decoder configured to reproduce the image from the latent representation. Once trained, the decoder is the generative artificial intelligence. As known in the art, a variational autoencoder encodes an input image into a probability distribution in a lower-dimensional latent space, samples a latent variable from that distribution, and then decodes the latent variable back into an output image that closely resembles the input image.

Step 1010 includes providing an artificial intelligence configured to produce a computer mesh file from a set of photographs of a previously-constructed system.

Step 1020 includes acquiring a plurality of images of the previously-constructed multi-component system 500. In illustrative embodiments, acquiring a plurality of images of the previously-constructed multi-component system 500 includes photographing the previously-constructed multi-component system 500 from a plurality of angles. The images may be acquired by a drone 920 imaging the previously-constructed multi-component system 500, or from a database of images of the previously-constructed multi-component system 500, to name but a few examples.

In preferred embodiments, acquiring a plurality of images of the previously-constructed multi-component system 500 includes capturing a set of images that, collectively, show a physical interface 523 between a master component 510 and a dependent component 520 in its entirety. The physical interface may appear, or be represented by, a closed curve. For example, where a rectangular dependent component 520 meets a flat surface of a master component 510, the physical interface in its entirety would be a complete rectangle. Where a circular dependent component 520 meets a flat surface of a master component 510, the physical interface in its entirety would be a circle or an ellipse. Where a circular dependent component 520 meets a curved surface of a master component 510, the physical interface in its entirety would have a saddle shape.

In illustrative embodiments, the plurality of input images are arranged into an input collage for input to the artificial intelligence.

Step 1030 includes generating a computer mesh file suitable for finite element analysis. Such a mesh file includes a mesh as described for example in one or more of FIG. 8D, FIG. 8E and FIG. 8F.

In illustrative embodiments, the computer mesh file includes a mesh comprising a plurality of nodes and a plurality of mesh elements at the interface 523 of the master component 510 and the dependent component 520. In some embodiments, generating a computer mesh file from the plurality of images of the previously-constructed multi-component system includes generating a CAD model of the previously-constructed multi-component system 500 from the plurality of images, the CAD model including a model of the master component 510, a model of the dependent component 520, and a model of said physical interface 523 between the master component 510 and the dependent component 510.

In preferred embodiments, each mesh element 892 generated by the generative artificial intelligence shares at least one node (i.e., one point 899) in common with an adjacent mesh element 892, and no node is part of only a single mesh element 892. In some embodiments, each mesh element 892 is a four-noded mesh element 892, in which the interior angle 897 between any two adjacent sides 895, 896 of the mesh element 892 is preferably ninety degrees (90 degrees), or within 60 degrees of a right angle (e.g., ninety degrees plus or minus 60 degrees). The interior angle 897 between any two adjacent sides 895, 896 of the mesh element 892 should not be less than 30 degrees. In illustrative embodiments, no four-noded mesh element 892 of a mesh 890 is a “twisted” element, in that no such mesh element 892 has two sides that cross each other (e.g., to make an “X” pattern). In some embodiments, each mesh element 892 has an aspect ratio of equal to or less than 4:1, where the aspect ratio of a mesh element 892 is defined as the ratio of the length of the mesh element to the width of the mesh element, for example as described above in connection with FIG. 8E.

It should be noted that the CAD model (FEA mesh) produced by the artificial intelligence is not merely a picture or point cloud, but is a computer file in a format typical for use and manipulation by a finite element analysis system.

Some embodiments include step 1040, which includes performing finite element analysis on the mesh generated at step 1030. Such finite element analysis may be performed on computer systems (e.g., CAD systems) known in the field of finite element analysis, which system use the mesh as input on which to perform the finite element analysis.

B. Creating CAD Model from Images

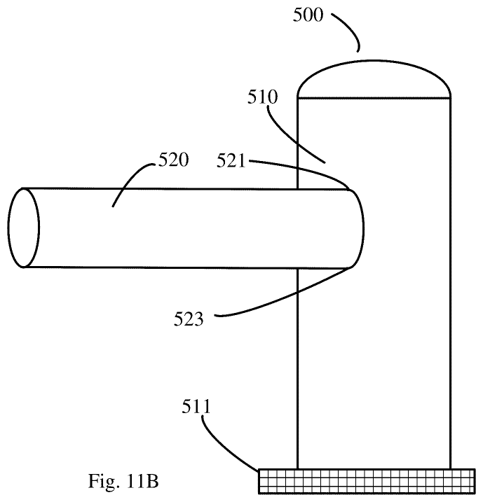

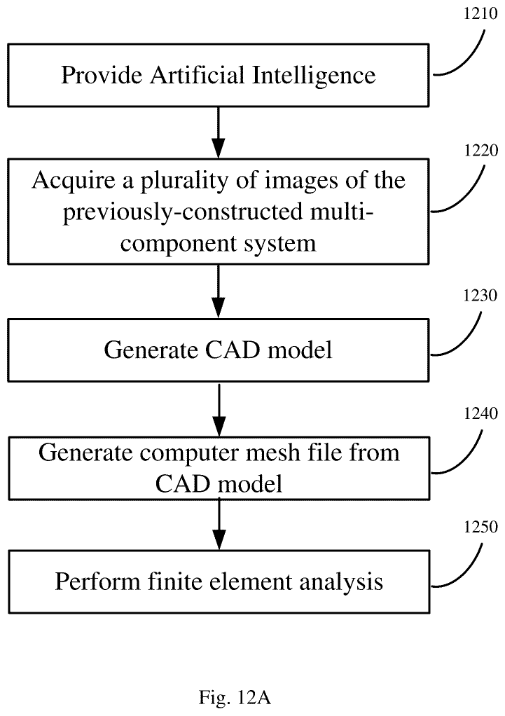

FIG. 11A is a flowchart of an embodiment of a method using generative artificial intelligence to generate a CAD model of a previously-constructed multi-component system 500. FIG. 11B schematically illustrates a CAD drawing created according to the method of FIG. 11A.

Step 1110 includes providing an artificial intelligence configured (i.e., trained) to generate a CAD model of a previously-constructed system 500 from a plurality of images of the previously-constructed system 500.

In some embodiments, such an artificial intelligence may be trained by a Generative Adversarial Network (“GAN”) as described in connection with FIG. 13.

Step 1120 includes acquiring the plurality of images of the previously-constructed system 500. In illustrative embodiments, the plurality of images of the previously-constructed system 500 are arranged into a collage as described herein, and provided to the artificial intelligence in the form of that collage.

Step 1130 includes providing the plurality of images (e.g., the collage) to the artificial intelligence acquired at step 1110, and processing the plurality of images using that artificial intelligence.

Step 1140 includes generating, by the artificial intelligence, a CAD model of the previously-constructed system 500. It should be noted that the CAD model produced by the artificial intelligence is not merely a picture or point cloud, but is a computer file in a format typical for use and manipulation by a CAD system, and having content for use and manipulation by a CAD system.

C. Creating a Mesh from a CAD Model

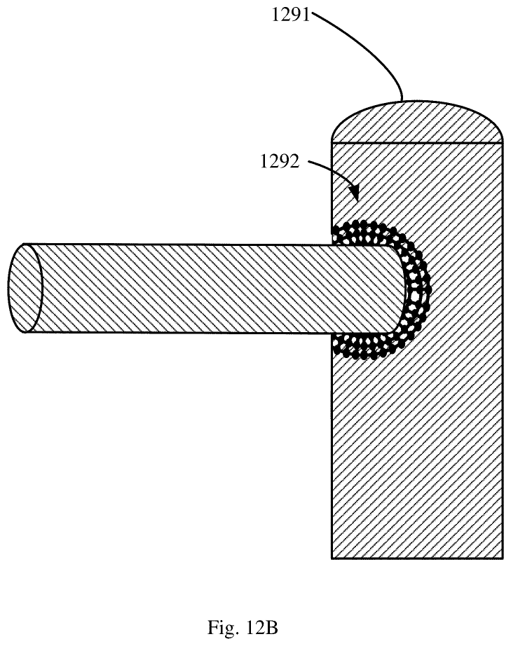

FIG. 12A is a flowchart of an embodiment of a method of creating, from a CAD model, a mesh suitable for finite element analysis.

Step 1210 includes providing an artificial intelligence configure (i.e., trained) to produce, from a CAD model, a mesh suitable for finite element analysis. Such an artificial intelligence may be trained by a GAN as schematically illustrated in FIG. 13.

The method also includes acquiring a CAD model of a previously-constructed system 500. In some embodiments, acquiring a CAD model of a previously-constructed system 500 includes retrieving a pre-existing CAD model from a computer memory or database.

In some embodiments, acquiring a CAD model of a previously-constructed system 500 includes acquiring a plurality of images (e.g., a collage) of the previously-constructed system 500 (step 1220) and generating a CAD model from those images (step 1230), as described above in connection with FIG. 11A.

Step 1240 includes generating a mesh file from the CAD drawing using the artificial intelligence acquired at step 1210. An illustrative embodiment of such a mesh file (graphically illustrated as mesh 1292) is schematically illustrated in FIG. 12B, shown in the context of the CAD model 1291 of the previously-constructed system.

Some embodiments include step 1250, which includes performing finite element analysis on the mesh file generated as step 1240.

A list of certain reference numbers here is presented below:
100: CAD system;
102: CAD system processing unit;
104: Computer monitor;
106: Keyboard;
108: Computer mouse;
120: Communications interface;
121: Bus;
130: Memory;
140: Shadow module;
141: Artificial intelligence module;
150: Orientation module;
160: Shadow module;
170: Points module;
180: Mesh module;
190: Finite element analysis module;
500: Multi-component structure or system;
510: Master component;
511: Base;
515: Center point of cross-section of master component;
520: Dependent component;
521: Interface end of dependent component;
523: Interface of dependent component and master component;
525: Interface plane of dependent component;
530: Longitudinal axis;
540: Point of intersection;
550: Light;
610: Shadow on surface of master component;
611: Outer edge of shadow;
620: Shadow plane;
630: Intermediate shadow on shadow plane;
890: Mesh;
892: Mesh element;
895: First side of mesh element;
896: Second side of mesh element;
897: Angle between adjacent sides of mesh element;
899: Point of a mesh;
910: Drone;
912: Drone camera.

Various embodiments may be characterized by the potential claims listed in the paragraphs following this paragraph (and before the actual claims provided at the end of this application). These potential claims form a part of the written description of this application. Accordingly, subject matter of the following potential claims may be presented as actual claims in later proceedings involving this application or any application claiming priority based on this application. Inclusion of such potential claims should not be construed to mean that the actual claims do not cover the subject matter of the potential claims. Thus, a decision to not present these potential claims in later proceedings should not be construed as a donation of the subject matter to the public.

Without limitation, potential subject matter that may be claimed (prefaced with the letter “P” so as to avoid confusion with the actual claims presented below) includes:
P1. A method for finite element analysis, in a computer, of a digital model of an interface between a master component and a dependent component of a physical apparatus, the method comprising:
obtaining a first digital model of the master component, the master component having a master surface;
obtaining a second digital model of the dependent component, the dependent component having a longitudinal axis and a cross section defining a connecting plane;
orienting the second digital model relative to the first digital model such that the longitudinal axis of the dependent component intersects a point of intersection on the first digital model;
casting a shadow of the cross section of the dependent component on a surface where the dependent component intersects the surface, the shadow defining a contour at its outer edge, said contour being a curve of intersection between the master component and the dependent component;
identifying a first group of master surface points on the surface of the master component, said first group of master surface points comprising a plurality of points forming the contour of the shadow on the surface of the master component;
identifying a second group of master surface points on the surface of the master component, said second group of master surface points comprising a plurality of points surrounding the first group of points;
defining a mesh comprising a plurality of mesh elements, each mesh element defined by a set of points from the first group of master surface points and the second group of master surface points; and
submitting the mesh to a finite element analysis system and performing finite element analysis of the mesh.
P2. The method of P1, wherein the surface is a surface of the master component.
P3. The method of any of P1-P2, wherein casting a shadow of the cross section of the dependent component on a surface comprises:
   creating an intermediate shadow of the cross section of the dependent component onto a two-dimensional shadow plane, said shadow plane parallel to a tangent plane tangent to the master surface at the point of intersection on the master surface where the dependent component intersects the master surface, the shadow having an outer edge and defining a contour at its outer edge, said contour being a curve of intersection between the shadow plane and the dependent component;
   selecting intermediate points on the curve of intersection; and
   translating said intermediate points to the master surface to produce the first group of master surface points.
P4. The method of P3, wherein the shadow plane is co-planar with the tangent plane.
P5. The method of P3, wherein the master surface comprises a flat surface defining a two-dimensional plane, and wherein said flat surface comprises the two-dimensional shadow plane.
P6. The method of P3, wherein the surface is the master surface and the master surface comprises a curved surface at the point of intersection, and the two-dimensional shadow plane comprises a floating surface disposed between the dependent component and the master component, the floating surface normal to a line that is normal to the master surface at the point of intersection.
P7. The method of any of P1-P6, wherein the second group of points is radially outward of the first group of points, relative to the point of intersection, and each mesh element of the plurality of mesh elements has an aspect ratio of less than or equal to 4:1.
P8. The method of any of P1-P7, wherein the shadow is cast by parallel light rays.
P9. A system for finite element analysis of a digital model of an interface between a master component specified by a first digital model and a dependent component specified by a second digital model, the dependent component having a longitudinal axis and a cross section defining a connecting plane, the system comprising:
   a CAD module configured to provide the first digital model and the second digital model;
   an orientation module configured for orienting the second digital model relative to the first digital model such that the longitudinal axis of the dependent component intersects a point of intersection on the first digital model;
   a shadow module configured for casting a shadow of the cross section of the dependent component on a surface where the dependent component intersects the surface, the shadow defining a contour at its outer edge, said contour being a curve of intersection between the master component and the dependent component;
   a points module configured for identifying a first group of master surface points on the surface of the master component, said first group of master surface points comprising a plurality of points forming the contour of the shadow on the surface of the master component;
   the points module also configured for identifying a second group of master surface points on the surface of the master component, said second group of master surface points comprising a plurality of points surrounding the first group of points;
   a mesh module configured for defining a mesh comprising a plurality of mesh elements, each mesh element defined by a set of points from the first group of master surface points and the second group of master surface points; and
   a finite element analysis module configured for submitting the mesh to a finite element analysis system and performing finite element analysis of the mesh.
P10. The system of P9, wherein the surface is a surface of the master component, and the shadow module configured for casting the shadow of the cross section of the dependent component on a surface of the master component.
P11. The system of any of P9-P10, wherein the system further comprises:
   the CAD module is further configured to provide a two-dimensional shadow plane parallel to a tangent plane tangent to the master surface at the point of intersection on the master surface where the dependent component intersects the master surface, and
   the shadow module is configured for creating an intermediate shadow of the cross section of the dependent component onto a shadow plane, the intermediate shadow having an outer edge and defining a contour at its outer edge, said contour being a curve of intersection between the master component and the dependent component;
   the points module is configured for selecting intermediate points on the curve of intersection; and
   translating said intermediate points to the master surface to produce the first group of master surface points.
P12. The system of P11, wherein the tangent plane is co-planar with the tangent plane.
P13. The system of P11, wherein the surface is a master surface of the master component, and the master surface comprises a curved surface at the point of intersection, and the two-dimensional shadow plane comprises a floating surface disposed between the dependent component and the master component, the floating surface normal to a line that is normal to the master surface at the point of intersection.
P14. A non-transitory computer readable medium having computer-executable code stored thereon, the computer-executable code, when executed by a computer processor, executing a method, the method comprising:
   providing a first digital model of the master component, the master component having a master surface;
   providing a second digital model of the dependent component, the dependent component having a longitudinal axis and a cross section defining a connecting plane;
   orienting the second digital model relative to the first digital model such that the longitudinal axis of the dependent component intersects a point of intersection on the first digital model;
   casting a shadow of the cross section of the dependent component on a surface where the dependent component intersects the surface, the shadow defining a contour at its outer edge, said contour being a curve of intersection between the master component and the dependent component;
   identifying a first group of master surface points on the surface of the master component, said first group of master surface points comprising a plurality of points forming the contour of the shadow on the surface of the master component;
   identifying a second group of master surface points on the surface of the master component, said second group of master surface points comprising a plurality of points surrounding the first group of points;
   defining a mesh comprising a plurality of mesh elements, each mesh element defined by a set of points from the first group of master surface points and the second group of master surface points; and
   submitting the mesh to a finite element analysis system and performing finite element analysis of the mesh.
P15. The non-transitory computer readable medium of P14, wherein the surface is a surface of the master component.
P16. The non-transitory computer readable medium of any of P14-P15, wherein casting the shadow of the cross section of the dependent component on a surface comprises:
   creating an intermediate shadow of the cross section of the dependent component onto a two-dimensional shadow plane, said shadow plane parallel to a tangent plane tangent to the master surface at the point of intersection on the master surface where the dependent component intersects the master surface, the shadow having an outer edge and defining a contour at its outer edge, said contour being a curve of intersection between the master component and the dependent component;
   selecting intermediate points on the curve of intersection; and
   translating said intermediate points to the master surface to produce the first group of master surface points.
P17. The non-transitory computer readable medium of P16, wherein the tangent plane is co-planar with the shadow plane.
P18. The non-transitory computer readable medium of P16, wherein the master surface comprises a flat surface defining a two-dimensional plane, and wherein said flat surface comprises the two-dimensional shadow plane.
P19. The non-transitory computer readable medium of any of P14-P18, wherein the surface is the master surface and the master surface comprises a curved surface at the point of intersection, and the two-dimensional shadow plane comprises a floating surface disposed between the dependent component and the master component, the floating surface normal to a line that is normal to the master surface at the point of intersection.
P20. The non-transitory computer readable medium of any of P14-P19, wherein the shadow is cast by parallel light rays.
P30. A non-transitory computer readable medium having computer-executable code stored thereon, the computer-executable code, when executed by a computer processor, executing a method, the method comprising the method of any of P1-P8.
P41. A method for finite element analysis, in a computer, of a previously-constructed multi-component system, the method comprising:
   acquiring, at a computer, a plurality of images of the previously-constructed multi-component system;
   identifying, by the computer, a master component of a previously-constructed multi-component system from the plurality of images;
   identifying, by the computer, a dependent component of a previously-constructed multi-component system from the plurality of images;
   identifying, by the computer, a physical interface between said master component and said dependent component; and
   generating, by the computer from the plurality of images of the previously-constructed multi-component system, a computer mesh file for finite element analysis, the computer mesh file comprising a mesh comprising a plurality of nodes and a plurality of mesh elements.
P42. The method of P41, wherein generating, from the plurality of images of the previously-constructed multi-component system, a computer mesh file for finite element analysis, the computer mesh file comprising a mesh comprising a plurality of nodes and a plurality of mesh elements, comprises:
   generating said computer mesh file using an artificial intelligence trained to generate the computer mesh file for finite element analysis from the plurality of images.
P43. The method of any of P41-P42, wherein generating a computer mesh file, from the plurality of images of the previously-constructed multi-component system, comprises:
   generating a CAD model of the previously-constructed multi-component system from the plurality of images, the CAD model including a model of said master component, a model of said dependent component, and a model of said physical interface between said master component and said dependent component.
P44. The method of P43, wherein generating, from the plurality of images of the previously-constructed multi-component system, a computer mesh file for finite element analysis, the computer mesh file comprising a mesh comprising a plurality of nodes and a plurality of mesh elements, comprises:
   generating said computer mesh file from the CAD model using an artificial intelligence trained to generate from the CAD model the computer mesh file for finite element analysis from the plurality of images.
P45. The method of any of P41-P44, wherein identifying a dependent component of a previously-constructed multi-component system from the plurality of images using an artificial intelligence trained to identify a dependent component of a previously-constructed multi-component system comprises:
   identifying the dependent component of a previously-constructed multi-component system from the plurality of images using an artificial intelligence trained to identify a dependent component of a previously-constructed multi-component system.
P46. The method of any of P41-P45, wherein identifying a physical interface between said master component and said dependent component comprises:
   identifying the physical interface between said master component and said dependent component using an artificial intelligence trained to identify such a physical interface.
P47. The method of any of P41-P46, further comprising performing finite element analysis on the mesh from the computer mesh file.
P48. The method of any of P41-P47, wherein generating, from the plurality of images of the previously-constructed multi-component system, a computer mesh file for finite element analysis, the computer mesh file comprising a mesh comprising a plurality of nodes and a plurality of mesh elements, comprises:
   generating said computer mesh file using a generative artificial intelligence trained to generate the computer mesh file for finite element analysis from the plurality of images.
P49. The method of any of P41-P48, wherein identifying by the computer, a master component of a previously-constructed multi-component system from the plurality of images comprises:
   identifying by the computer, a master component of a previously-constructed multi-component system from the plurality of images using an artificial intelligence trained to identify a master component of a previously-constructed multi-component system.
P51. A system for finite element analysis of a previously-constructed multi-component system, the system comprising:
   a memory configured to store a set of images of the previously-constructed multi-component system;
   an artificial intelligence module configured to identify, from the set of images of the previously-constructed multi-component system, a physical interface between a master component of the previously-constructed multi-component system, and a dependent component of the previously-constructed multi-component system;
   a mesh module configured to generate, from the plurality of images of the previously-constructed multi-component system, a computer mesh file for finite element analysis, the computer mesh file comprising a mesh comprising a plurality of nodes defining a plurality of mesh elements of the physical interface of the previously-constructed multi-component system.
P52. The system of P51, further comprising:
   an artificial intelligence module configured to identify, from the set of images of the previously-constructed multi-component system, the master component of a previously-constructed multi-component system.
P53. The system of any of P51-P52, further comprising:
   an artificial intelligence module configured to identify, from the set of images of the previously-constructed multi-component system, the dependent component of a previously-constructed multi-component system.
P54. The system of any of P51-P53, wherein the mesh module comprises:
   an artificial intelligence module trained to generate the computer mesh file for finite element analysis from the plurality of images.
P55. The system of P54, wherein the artificial intelligence module trained to generate the computer mesh file for finite element analysis from the plurality of images comprises a generative artificial intelligence.
P56. The system of any of P51-P55, further comprising:
   a CAD module configured to generate a CAD model of the previously-constructed multi-component system from the plurality of images, the CAD model including a model of said master component, a model of said dependent component, and a model of said physical interface between said master component and said dependent component.
P57. The system of P56, wherein the mesh module configured to generate, from the plurality of images of the previously-constructed multi-component system, a computer mesh file for finite element analysis, is configured:
   to generate said computer mesh file from the CAD model using an artificial intelligence trained to generate from the CAD model the computer mesh file for finite element analysis from the plurality of images.
P58. The system of P57, wherein artificial intelligence trained to generate from the CAD model the computer mesh file comprises a generative artificial intelligence.
P61. A non-transitory computer-readable medium having computer executable code thereon, the computer executable code, when executed by a computer system, causing the computer system to perform a method, the method comprising:
   acquiring a plurality of images of the previously-constructed multi-component system;
   identifying a master component of a previously-constructed multi-component system from the plurality of images using an artificial intelligence trained to identify a master component of a previously-constructed multi-component system;
   identifying a dependent component of a previously-constructed multi-component system from the plurality of images;
   identifying the physical interface between said master component and said dependent component; and
   generating, from the plurality of images of the previously-constructed multi-component system, a computer mesh file for finite element analysis, the computer mesh file comprising a mesh comprising a plurality of nodes defining a plurality of mesh elements.
P62. The non-transitory computer-readable medium of P61, wherein generating, from the plurality of images of the previously-constructed multi-component system, a computer mesh file for finite element analysis, the computer mesh file comprising a mesh comprising a plurality of nodes defining a plurality of mesh elements, comprises:
   generating said computer mesh file using an artificial intelligence trained to generate the computer mesh file for finite element analysis from the plurality of images.
P63. The non-transitory computer-readable medium of any of P61-P62, wherein generating, from the plurality of images of the previously-constructed multi-component system, a computer mesh file for finite element analysis, the computer mesh file comprising a mesh comprising a plurality of nodes defining a plurality of mesh elements, comprises:
   generating said computer mesh file using a generative artificial intelligence trained to generate the computer mesh file for finite element analysis from the plurality of images.
P64. The non-transitory computer-readable medium of any of P61-P63, wherein generating, from the plurality of images of the previously-constructed multi-component system, a computer mesh file for finite element analysis comprises:
   generating a CAD model of the previously-constructed multi-component system from the plurality of images, the CAD model including a model of said master component, a model of said dependent component, and a model of said physical interface between said master component and said dependent component.
P65. The non-transitory computer-readable medium of any of P61-P64, identifying a dependent component of a previously-constructed multi-component system from the plurality of images comprises:
   identifying the dependent component using an artificial intelligence trained to identify, from images of the previously-constructed multi-component system, a dependent component of a previously-constructed multi-component system.
P66. The non-transitory computer-readable medium of any of P61-P65, wherein identifying the physical interface between said master component and said dependent component comprises:
   identifying the physical interface between said master component and said dependent component using an artificial intelligence trained to identify such a physical interface.
P67. The non-transitory computer-readable medium of P61-P66, further comprising performing finite element analysis on the mesh from the computer mesh file.
P101. A method of comprising:
   providing an artificial intelligence image generator trained to generate a computer mesh file from a plurality of photographs of a system;
   obtaining a plurality of photographs of a previously-constructed system;
   causing the artificial intelligence to generate a computer mesh file of the previously-constructed system, which computer mesh file is configured for finite element analysis by a finite element analysis system.
P102. The method of P101, wherein the plurality of photographs of the previously-constructed system comprises a collage of the plurality of photographs, in which the plurality of photographs are arranged relative to one another according to a previously-defined pattern.
P103. The method of any of P101-P102, wherein providing an artificial intelligence trained to generate a computer mesh file from a plurality of photographs of a system comprises:
   training an artificial intelligence image-to-image generator using a generative artificial intelligence comprising a source of reference images of previously-constructed reference systems, each such image including a mesh suitable for finite element analysis, and a discriminator, the discriminator comprising a second artificial intelligence trained to discriminate between an image generated by the generator and one or more reference images.
P104. The method of P103, wherein each reference image comprises a collage of a plurality of images of a corresponding previously-constructed reference system, such plurality of images arranged in the collage relative to one another according to the previously-defined pattern.
P105. The method of any of P101, wherein providing an artificial intelligence trained to generate a computer mesh file from a plurality of photographs of a system comprises:
   training an artificial intelligence image-to-image generator by providing a large set of images to a variational autoencoder, where each image of the large set of images includes a previously-constructed system having a mesh suitable for finite element analysis.
P106. The method of any of P101-P105, wherein the computer mesh file comprises a plurality of triangular mesh elements.
P107. The method of any of P101-P106, wherein the computer mesh file comprises a plurality of four-noded mesh elements.
P108. The method of any of P101-P107, wherein the computer mesh file comprises a plurality nodes, each node is a member of at least two mesh elements.
P109. The method of any of P101-P108, wherein the plurality of photographs of the previously-constructed system comprises photographs collectively showing a 360 degree view of the previously-constructed system.
P110. The method of any of P101-P109, further comprising performing finite element analysis on the computer mesh file.
P111. A computer-implemented system comprising:
   an artificial intelligence image generator module trained to generate a computer mesh file from a plurality of photographs of a system;
   a source of photographs of a previously-constructed system, the source in data communication with the artificial intelligence image generator module;
   a memory configured to store a corresponding computer mesh file generated from the photographs of the previously-constructed system by the artificial intelligence image generator.
P112. The system of P111, further comprising a finite element analysis module in data communication with the memory and configured to perform finite element analysis on the corresponding computer mesh file.
P113. The system of any of P111-P112, further comprising a drone having a camera, the drone craft configured to fly near the previously-constructed system and capture the photographs of a previously-constructed system.
P114. The system of any of P111-P113, wherein the artificial intelligence image generator module is trained by a generative artificial intelligence comprising a source of reference images of previously-constructed reference systems, each such image including a mesh suitable for finite element analysis, and a discriminator, the discriminator comprising a second artificial intelligence trained to discriminate between an image generated by the generator and one or more reference images.
P115. The system of any of P111-P113, wherein the artificial intelligence image generator module is trained by providing a large set of images to a variational autoencoder, where each image of the large set of images includes a previously-constructed system having a mesh suitable for finite element analysis.
P116. A non-transitory computer-readable medium having computer executable code thereon, the computer executable code, when executed by a computer system, causing the computer system to perform a method, the code comprising:
   code for providing an artificial intelligence image generator trained to generate a computer mesh file from a plurality of photographs of a system;
   code for obtaining a plurality of photographs of a previously-constructed system, said plurality of photographs of the previously-constructed system comprising a collage of the plurality of photographs, in which the plurality of photographs are arranged relative to one another according to a previously-defined pattern; and
   code for causing the artificial intelligence to generate a computer mesh file of the previously-constructed system, which computer mesh file is configured for finite element analysis by a finite element analysis system.
P117. The non-transitory computer-readable medium of P116, wherein the artificial intelligence image generator was trained using a generative artificial intelligence comprising a source of reference images of previously-constructed reference systems, each such image including a mesh suitable for finite element analysis, and a discriminator, the discriminator comprising a second artificial intelligence trained to discriminate between an image generated by the generator and one or more reference images.
P118. The non-transitory computer-readable medium of P117, wherein each reference image comprises a collage of a plurality of images of a corresponding previously-constructed reference system, such plurality of images arranged in the collage relative to one another according to the previously-defined pattern.
P119. The non-transitory computer-readable medium of any of P116-P118, wherein the artificial intelligence image generator was trained by providing a large set of images to a variational autoencoder, where each image of the large set of images includes a previously-constructed system having a mesh suitable for finite element analysis.
P120. The non-transitory computer-readable medium of any of P116-P119, wherein the computer mesh file comprises a plurality of nodes, each node is a member of at least two mesh elements.
P121. The non-transitory computer-readable medium of P116, wherein the method comprises any of the methods of P101-P110.

Various embodiments of this disclosure may be implemented at least in part in any conventional computer programming language. For example, some embodiments may be implemented in a procedural programming language (e.g., “C”), or in an object-oriented programming language (e.g., “C++”), or in Python, R, Java, LISP or Prolog. Other embodiments of this disclosure may be implemented as preprogrammed hardware elements (e.g., application specific integrated circuits, FPGAs, and digital signal processors), or other related components.

In an alternative embodiment, the disclosed apparatus and methods may be implemented as a computer program product for use with a computer system. Such implementation may include a series of computer instructions fixed either on a tangible medium, such as a non-transitory computer readable medium (e.g., a diskette, CD-ROM, ROM, FLASH memory, or fixed disk). The series of computer instructions can embody all or part of the functionality previously described herein with respect to the system.

Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies.

Among other ways, such a computer program product may be distributed as a removable medium with accompanying printed or electronic documentation (e.g., shrink wrapped software), preloaded with a computer system (e.g., on system ROM or fixed disk), or distributed from a server or electronic bulletin board over the network (e.g., the Internet or World Wide Web). Of course, some embodiments of this disclosure may be implemented as a combination of both software (e.g., a computer program product) and hardware. Still other embodiments of this disclosure are implemented as entirely hardware, or entirely software.

Computer program logic implementing all or part of the functionality previously described herein may be executed at different times on a single processor (e.g., concurrently) or may be executed at the same or different times on multiple processors and may run under a single operating system process/thread or under different operating system processes/threads. Thus, the term “computer process” refers generally to the execution of a set of computer program instructions regardless of whether different computer processes are executed on the same or different processors and regardless of whether different computer processes run under the same operating system process/thread or different operating system processes/threads.

The embodiments of the invention described above are intended to be merely exemplary; numerous variations and modifications will be apparent to those skilled in the art. Such variations and modifications are intended to be within the scope of the present invention as defined by any of the appended claims.

What is claimed is:

1. A method of comprising:
providing an artificial intelligence image generator trained to generate a computer mesh file from a plurality of photographs of a system;
obtaining a plurality of photographs of a previously-constructed system;
causing the artificial intelligence to generate a computer mesh file of the previously-constructed system, which computer mesh file is configured for finite element analysis by a finite element analysis system.

2. The method of claim 1, wherein the plurality of photographs of the previously-constructed system comprises a collage of the plurality of photographs, in which the plurality of photographs are arranged relative to one another according to a previously-defined pattern.

3. The method of claim 2, wherein providing an artificial intelligence trained to generate a computer mesh file from a plurality of photographs of a system comprises:
training an artificial intelligence image-to-image generator using a generative artificial intelligence comprising a source of reference images of previously-constructed reference systems, each such image including a mesh suitable for finite element analysis, and a discriminator, the discriminator comprising a second artificial intelligence trained to discriminate between an image generated by the generator and one or more reference images.

4. The method of claim 3, wherein each reference image comprises a collage of a plurality of images of a corresponding previously-constructed reference system, such plurality of images arranged in the collage relative to one another according to the previously-defined pattern.

5. The method of claim 1, wherein providing an artificial intelligence trained to generate a computer mesh file from a plurality of photographs of a system comprises:
training an artificial intelligence image-to-image generator by providing a large set of images to a variational autoencoder, where each image of the large set of images includes a previously-constructed system having a mesh suitable for finite element analysis.

6. The method of claim 1, wherein the computer mesh file comprises a plurality of triangular mesh elements.

7. The method of claim 1, wherein the computer mesh file comprises a plurality of four-noded mesh elements.

8. The method of claim 1, wherein the computer mesh file comprises a plurality of nodes, each node is a member of at least two mesh elements.

9. The method of claim 1, wherein the plurality of photographs of the previously-constructed system comprises photographs collectively showing a 360 degree view of the previously-constructed system.

10. The method of claim 1, further comprising performing finite element analysis on the computer mesh file.

11. A computer-implemented system comprising:
an artificial intelligence image generator module trained to generate a computer mesh file from a plurality of photographs of a system;
a source of photographs of a previously-constructed system, the source in data communication with the artificial intelligence image generator module; and
a memory configured to store a corresponding computer mesh file generated from the photographs of the previously-constructed system by the artificial intelligence image generator.

12. The system of claim 11, further comprising a finite element analysis module in data communication with the memory and configured to perform finite element analysis on the corresponding computer mesh file.

13. The system of claim 11, further comprising a drone having a camera, the drone craft configured to fly near the previously-constructed system and capture the photographs of a previously-constructed system.

14. The system of claim 11, wherein the artificial intelligence image generator module is trained by a generative artificial intelligence comprising a source of reference images of previously-constructed reference systems, each such image including a mesh suitable for finite element analysis, and a discriminator, the discriminator comprising a second artificial intelligence trained to discriminate between an image generated by the generator and one or more reference images.

15. The system of claim 11, wherein the artificial intelligence image generator module is trained by providing a large set of images to a variational autoencoder, where each image of the large set of images includes a previously-constructed system having a mesh suitable for finite element analysis.

16. A non-transitory computer-readable medium having computer executable code thereon, the computer executable code, when executed by a computer system, causing the computer system to perform a method, the code comprising:
code for providing an artificial intelligence image generator trained to generate a computer mesh file from a plurality of photographs of a system;
code for obtaining a plurality of photographs of a previously-constructed system, said plurality of photographs of the previously-constructed system comprising a collage of the plurality of photographs, in which the plurality of photographs are arranged relative to one another according to a previously-defined pattern; and
code for causing the artificial intelligence to generate a computer mesh file of the previously-constructed system, which computer mesh file is configured for finite element analysis by a finite element analysis system.

17. The non-transitory computer-readable medium of claim 16, wherein the artificial intelligence image generator was trained using a generative artificial intelligence comprising a source of reference images of previously-constructed reference systems, each such image including a mesh suitable for finite element analysis, and a discriminator, the discriminator comprising a second artificial intelligence trained to discriminate between an image generated by the generator and one or more reference images.

18. The non-transitory computer-readable medium of claim 17, wherein each reference image comprises a collage of a plurality of images of a corresponding previously-constructed reference system, such plurality of images arranged in the collage relative to one another according to the previously-defined pattern.

19. The non-transitory computer-readable medium of claim 16, wherein the artificial intelligence image generator was trained by providing a large set of images to a variational autoencoder, where each image of the large set of images includes a previously-constructed system having a mesh suitable for finite element analysis.

20. The non-transitory computer-readable medium of claim 16, wherein the computer mesh file comprises a plurality of nodes, each node is a member of at least two mesh elements.
